(19) United States
(12) Patent Application Publication
(10) Pub. No.: US 2020/0295016 A1
(43) Pub. Date: Sep. 17, 2020

(54) SEMICONDUCTOR MEMORY DEVICE

(71) Applicant: Toshiba Memory Corporation, Minato-ku (JP)

(72) Inventors: Hisashi HARADA, Yokkaichi (JP); Ayaha Hachisuga, Yokkaichi (JP); Jun Nishimura, Kuwana (JP)

(73) Assignee: Toshiba Memory Corporation, Minato-ku (JP)

(21) Appl. No.: 16/564,434

(22) Filed: Sep. 9, 2019

(30) Foreign Application Priority Data
Mar. 12, 2019 (JP) 2019-044879

(51) Int. Cl. H01L 27/1157; H01L 27/11524; H01L 27/11556; H01L 27/11519; H01L 21/28; H01L 27/11582; H01L 27/11565; H01L 23/522; H01L 23/528; H01L 21/768

(52) U.S. Cl. CPC H01L 27/1157; H01L 27/11524; H01L 27/11556; H01L 27/11519; H01L 29/40114; H01L 21/76877; H01L 27/11565; H01L 29/40117; H01L 23/5226; H01L 23/5283; H01L 21/76816; H01L 27/11582

(57) ABSTRACT

A semiconductor memory device according to an embodiment includes first to third conductive layers, first and second pillars, first and second contacts, and first to third members. The first pillar penetrates the first and second conductive layers in a first area. A second pillar penetrates the first and third conductive layers in the first area. The first and second contacts are provided on the second and third conductive layers respectively in a second area. The first and second members are provided between the second and third conductive layers in the first and second area, respectively. The third member penetrates the first conductive layers. The third member is in contact with each of the second and third conductive layers, and the first and second members.

### CROSS-REFERENCE TO RELATED APPLICATIONS

This application is based upon and claims the benefit of priority from Japanese Patent Application No. 2019-044879, filed Mar. 12, 2019, the entire contents of which are incorporated herein by reference.

### FIELD

Embodiments described herein relate generally to a semiconductor memory device.

### BACKGROUND

A NAND-type flash memory capable of storing data in a nonvolatile manner is known.

### BRIEF DESCRIPTION OF THE DRAWINGS

FIG. 1 is a block diagram illustrating a configuration example of a semiconductor memory device according to a first embodiment;

FIG. 2 is a circuit diagram illustrating an example of a circuit configuration of a memory cell array included in the semiconductor memory device according to the first embodiment;

FIG. 3 is a plan view illustrating an example of a planar layout of the memory cell array included in the semiconductor memory device according to the first embodiment;

FIG. 4 is a plan view illustrating an example of a detailed planar layout in a cell area of the memory cell array included in the semiconductor memory device according to the first embodiment;

FIG. 5 is a cross-sectional view, taken along line V-V in FIG. 4, illustrating an example of a cross-sectional structure in the cell area of the memory cell array included in the semiconductor memory device according to the first embodiment;

FIG. 6 is a cross-sectional view, taken along line VI-VI in FIG. 5, illustrating an example of a cross-sectional structure of a memory pillar in the semiconductor memory device according to the first embodiment;

FIG. 7 is a plan view illustrating an example of a detailed planar layout in a hookup area of the memory cell array included in the semiconductor memory device according to the first embodiment;

FIG. 8 is a cross-sectional view, taken along line VIII-VIII in FIG. 7, illustrating an example of a cross-sectional structure in the hookup area of the memory cell array included in the semiconductor memory device according to the first embodiment;

FIG. 9 is a cross-sectional view, taken along line IX-IX in FIG. 7, illustrating an example of a cross-sectional structure in the hookup area of the memory cell array included in the semiconductor memory device according to the first embodiment;

FIG. 10 is a cross-sectional view, taken along line X-X in FIG. 9, illustrating an example of a cross-sectional structure of a contact in the semiconductor memory device according to the first embodiment;

FIG. 11 is a cross-sectional view, taken along line XI-XI in FIG. 9, illustrating an example of a cross-sectional structure of a support pillar in the semiconductor memory device according to the first embodiment;

FIG. 12 is a flowchart illustrating an example of a manufacturing method of the semiconductor memory device according to the first embodiment;

FIG. 13 is a cross-sectional view of a memory cell array, illustrating an example of a cross-sectional structure during the manufacture of the semiconductor memory device according to the first embodiment;

FIG. 14 is a plan view of the memory cell array, illustrating an example of a planar layout during the manufacture of the semiconductor memory device according to the first embodiment;

FIG. 15 is a cross-sectional view of the memory cell array, taken along line XV-XV in FIG. 14, illustrating an example of the cross-sectional structure during the manufacture of the semiconductor memory device according to the first embodiment;

FIG. 16 is a cross-sectional view of the memory cell array, illustrating an example of the cross-sectional structure during the manufacture of the semiconductor memory device according to the first embodiment;

FIG. 17 is a plan view of the memory cell array, illustrating an example of the planar layout during the manufacture of the semiconductor memory device according to the first embodiment;

FIG. 18 is a cross-sectional view of the memory cell array, taken along line XVIII-XVIII in FIG. 17, illustrating an example of the cross-sectional structure during the manufacture of the semiconductor memory device according to the first embodiment;

FIG. 19, FIG. 20 and FIG. 21 are cross-sectional views of the memory cell array, illustrating examples of the cross-sectional structure during the manufacture of the semiconductor memory device according to the first embodiment;

FIG. 22 is a plan view of the memory cell array, illustrating an example of the planar layout during the manufacture of the semiconductor memory device according to the first embodiment;

FIG. 23 is a cross-sectional view of the memory cell array, taken along line XXIII-XXIII in FIG. 22, illustrating an example of the cross-sectional structure during the manufacture of the semiconductor memory device according to the first embodiment;

FIG. 24 is a plan view of the memory cell array, illustrating an example of the planar layout during the manufacture of the semiconductor memory device according to the first embodiment;

FIG. 25 is a cross-sectional view of the memory cell array, taken along line XXV-XXV in FIG. 24, illustrating an example of the cross-sectional structure during the manufacture of the semiconductor memory device according to the first embodiment;

FIG. 26 is a cross-sectional view of the memory cell array, illustrating an example of the cross-sectional structure during the manufacture of the semiconductor memory device according to the first embodiment;

FIG. 27 is a plan view of the memory cell array, illustrating an example of the planar layout during the manufacture of the semiconductor memory device according to the first embodiment;

FIG. 28 is a cross-sectional view of the memory cell array, taken along line XXVIII-XXVIII in FIG. 27, illustrating an example of the cross-sectional structure during the manufacture of the semiconductor memory device according to the first embodiment;

FIG. 29 is a cross-sectional view of the memory cell array, illustrating an example of the cross-sectional structure during the manufacture of the semiconductor memory device according to the first embodiment;

FIG. 30 is a flowchart illustrating an example of a manufacturing method of a semiconductor memory device according to a second embodiment;

FIG. 31, FIG. 32, FIG. 33 and FIG. 34 are cross-sectional views of the memory cell array, illustrating examples of the cross-sectional structure during the manufacture of the semiconductor memory device according to the second embodiment;

FIG. 35 is a flowchart illustrating an example of a manufacturing method of a semiconductor memory device according to a third embodiment;

FIG. 36 is a plan view of the memory cell array, illustrating an example of the planar layout during the manufacture of the semiconductor memory device according to the third embodiment;

FIG. 37 is a cross-sectional view of the memory cell array, taken along line XXXVII-XXXVII in FIG. 36, illustrating an example of the cross-sectional structure during the manufacture of the semiconductor memory device according to the third embodiment;

FIG. 38 is a plan view of the memory cell array, illustrating an example of the planar layout during the manufacture of the semiconductor memory device according to the third embodiment;

FIG. 39 is a cross-sectional view of the memory cell array, illustrating an example of the cross-sectional structure during the manufacture of the semiconductor memory device according to the third embodiment;

FIG. 40 is a plan view illustrating an example of a detailed planar layout in a hookup area of a memory cell array included in a semiconductor memory device according to a fourth embodiment;

FIG. 41 is a cross-sectional view, taken along line XLI-XLI in FIG. 40, illustrating an example of a cross-sectional structure in the hookup area of the memory cell array included in the semiconductor memory device according to the fourth embodiment;

FIG. 42 is a cross-sectional view, taken along line XLII-XLII in FIG. 41, illustrating an example of a cross-sectional structure of a contact in the semiconductor memory device according to the fourth embodiment;

FIG. 43 is a flowchart illustrating an example of a manufacturing method of the semiconductor memory device according to the fourth embodiment;

FIG. 44 is a plan view of the memory cell array, illustrating an example of the planar layout during the manufacture of the semiconductor memory device according to the fourth embodiment;

FIG. 45 is a cross-sectional view, taken along line XLV-XLV in FIG. 44, illustrating an example of the cross-sectional structure during the manufacture of the semiconductor memory device according to the fourth embodiment; and

FIG. 46 is a cross-sectional view illustrating an example of a cross-sectional structure of a support pillar in a semiconductor memory device according to a modification of the first embodiment.

### DETAILED DESCRIPTION

In general, according to one embodiment, a semiconductor memory device includes a substrate, a plurality of first conductive layers, a second conductive layer, a third conductive layer, a first pillar, a second pillar, a first contact, a second contact, a first member, a second member, and a third member. The substrate includes a first area and a second area adjacent to the first area. The plurality of first conductive layers are provided above the substrate of the first area and the second area. The first conductive layers are stacked at intervals in a first direction. The second conductive layer is provided above an uppermost first conductive layer of the first conductive layers. The third conductive layer is provided above the uppermost first conductive layer and is provided in the same layer as the second conductive layer. The third conductive layer and the second conductive layer are separated from each other. The first pillar is provided to penetrate the first conductive layers and the second conductive layer in the first area. An intersection portion between the first pillar and each of the first conductive layers functions as a memory cell transistor. An intersection portion between the first pillar and the second conductive layer functions as a select transistor. A second pillar is provided to penetrate the first conductive layers and the third conductive layer in the first area. An intersection portion between the second pillar and each of the first conductive layers functions as a memory cell transistor. An intersection portion between the second pillar and the third conductive layer is functions as a select transistor. The first contact is provided on the second conductive layer in the second area. The second contact is provided on the third conductive layer in the second area. The first member is provided between the second conductive layer and the third conductive layer in the first area. The second member is provided between the second conductive layer and the third conductive layer in the second area. The third member is extending in the first direction and is provided to penetrate the first conductive layers. The third member is in contact with each of the second conductive layer, the third conductive layer, the first member and the second member.

Hereinafter, the embodiments will be described with reference to the accompanying drawings. Each embodiment is an example of a device or a method for embodying a technical concept of the invention. The drawings are schematic or conceptual ones. The dimensions, ratios, etc. in the drawings do not necessarily agree with the actual ones. The technical concept of the present invention is not specified by shapes, structures, dispositions, etc. of constituent elements.

In the description below, constituent elements having substantially the same functions and configurations will be denoted by the same reference symbols. The numbers after the letters constituting the reference symbols are used to distinguish elements which are denoted by the reference symbols including the same letters and which have similar configurations. If there is no need of mutually distinguishing the elements which are denoted by the reference symbols that include the same letters, the same elements are denoted by the reference symbols that include only the same letters.

### [1] First Embodiment

Hereinafter, a semiconductor memory device 1 according to a first embodiment will be described.

[1-1] Configuration of Semiconductor Memory Device 1

[1-1-1] Entire Configuration of Semiconductor Memory Device 1

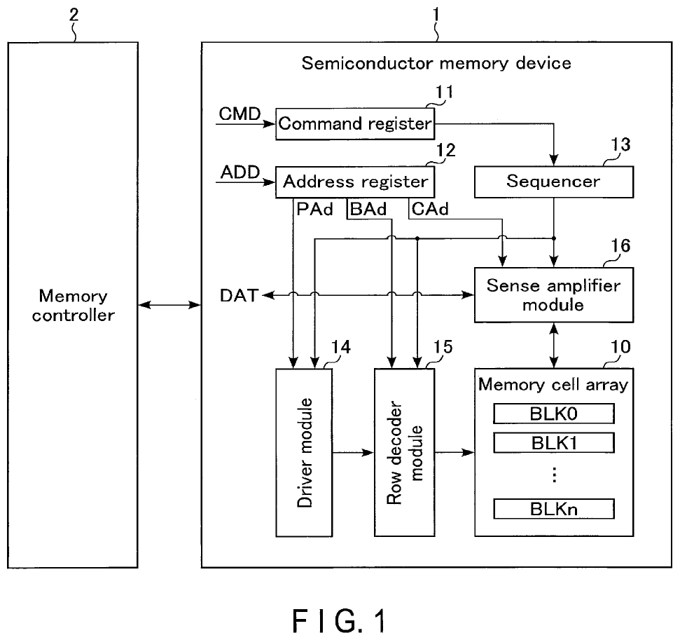

FIG. 1 illustrates a configuration example of the semiconductor memory device 1 according to the first embodiment. The semiconductor memory device 1 is a NAND-type flash memory which can store data nonvolatilely, and is controlled by an external memory controller 2. Communication between the semiconductor memory device 1 and the memory controller 2 supports, for example, a NAND interface standard.

As illustrated in FIG. 1, the semiconductor memory device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer of 1 or more). The block BLK is a set of a plurality of memory cells which can store data nonvolatilely, and the block BLK is used, for example, as an erase unit of data. In addition, in the memory cell array 10, a plurality of bit lines and a plurality of word lines are provided. Each memory cell is associated with, for example, one bit line and one word line. A detailed configuration of the memory cell array 10 will be described later.

The command register 11 holds a command CMD which the semiconductor memory device 1 has received from the memory controller 2. The command CMD includes, for example, instructions to cause the sequencer 13 to perform a read operation, a write operation, an erase operation and the like.

The address register 12 holds address information ADD which the semiconductor memory device 1 has received from the memory controller 2. The address information ADD includes a block address BAd, a page address PAd, and a column address CAd. For example, the block address BAd, page address PAd and column address CAd are used to select a block BLK, a word line and a bit line, respectively.

The sequencer 13 controls the operation of the entire semiconductor memory device 1. For example, the sequencer 13 controls the driver module 14, the row decoder module 15, the sense amplifier module 16 and the like, based on the command CMD held in the command register 11, thereby executing a read operation, a write operation, an erase operation and the like.

The driver module 14 generates a voltage that is to be used in the read operation, write operation, erase operation and the like. Then, the driver module 14 applies the generated voltage to a signal line corresponding to a selected word line, for example, based on the page address PAd held in the address register 12.

The row decoder module 15 selects one block BLK in the memory cell array 10, based on the block address BAd held in the address register 12. Then, the row decoder module 15 transfers, for example, a voltage applied to the signal line corresponding to the selected word line, to the selected word line in the selected block BLK.

In the write operation, the sense amplifier module 16 apples a desired voltage to each bit line in accordance with write data DAT received from the memory controller 2. In the read operation, the sense amplifier module 16 determines data stored in a memory cell, based on the voltage of the bit line, and transfers a result of the determination to the memory controller 2 as read data DAT.

The above-described semiconductor memory device 1 and memory controller 2 may be combined to constitute one semiconductor device. Examples of this semiconductor device include a memory card such as an SD™ card, a solid-state drive (SSD), and the like.

[1-1-2] Circuit Configuration of Memory Cell Array 10

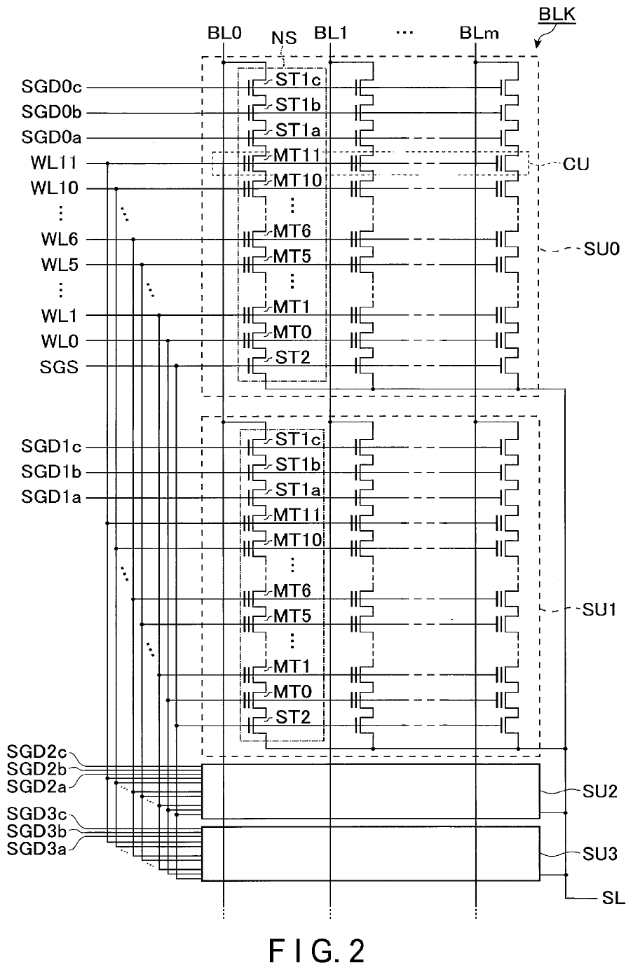

FIG. 2 illustrates an example of a circuit configuration of the memory cell array 10 included in the semiconductor memory device 1 according to the first embodiment, by extracting one of the blocks BLK included in the memory cell array 10. As illustrated in FIG. 2, the block BLK includes, for example, four string units SU0 to SU3.

Each string unit SU includes a plurality of NAND strings NS which are associated with bit lines BL0 to BLm (m is an integer of 1 or more), respectively. Each NAND string NS includes, for example, memory cell transistors MT0 to MT11, and select transistors ST1a, ST1b, ST1c, and ST2. The memory cell transistor MT includes a control gate and a charge storage layer, and stores data nonvolatilely. Each of the select transistors ST1a, ST1b, ST1c, and ST2 is used to select the string unit SU during various operations.

In each NAND string NS, the select transistors ST1a, ST1b and ST1c are connected in series, and the memory transistors MT0 to MT11 are connected in series. One end of the series-connected select transistors ST1a, ST1b and ST1c is connected to the associated bit line BL, and the other end thereof is connected to one end of the series-connected memory transistors MT0 to MT11. One end of the select transistor ST2 is connected to the other end of the series-connected memory transistors MT0 to Mil, and the other end of the select transistor ST2 is connected to the source line SL.

In the same block BLK, the control gates of the memory cell transistors MT0 to MT11 are commonly connected to word lines WL0 to WL11, respectively. The gates of the select transistors ST1a, ST1b and ST1c in the string unit SU0 are commonly connected to select gate lines SGD0a, SGD0b and SGD0c, respectively. The gates of the select transistors ST1a, ST1b and ST1c in the string unit SU1 are commonly connected to select gate lines SGD1a, SGD1b and SGD1c, respectively. The gates of the select transistors ST1a, ST1b and ST1c in the string unit SU2 are commonly connected to select gate lines SGD2a, SGD2b and SGD2c, respectively. The gates of the select transistors ST1a, ST1b and ST1c in the string unit SU3 are commonly connected to select gate lines SGD3a, SGD3b and SGD3c, respectively. The gates of the select transistors ST2 in the same block BLK are commonly connected to a select gate line SGS.

In the above-described circuit configuration of the memory cell array 10, the word lines WL0 to WL5 correspond to memory holes LMH to be described later, and the word lines WL6 to WL11 correspond to memory holes UMH to be described later. Each bit line BL is shared by the NAND strings NS to which the same column address is allocated in each string unit SU. The source line SL is shared by, for example, a plurality of blocks BLK.

A set of memory cell transistors MT connected to a common word line WL in one string unit SU is referred to as, for example, a cell unit CU. For example, the storage capacity of the cell unit CU including memory cell transistors MT each storing one-bit data is defined as “one-page data.” The cell unit CU may have a storage capacity of data of two or more pages, according to the number of bits of data to be stored in the memory cell transistor MT.

Note that the circuit configuration of the memory cell array 10 included in the semiconductor memory 1 according to the first embodiment is not limited to the configuration described above. For example, the number of memory cell transistors MT and the number of select transistors ST1 and ST2, which are included in each NAND string NS, may be freely selected. The number of string units SU included in each block BLK may be freely selected.

Besides, one or more dummy word lines may be provided between the word lines WL5 and WL6. When a dummy word line is provided, a dummy transistor is provided between the memory cell transistors MT5 and MT6 of each NAND string NS, with the number of dummy transistors being set according to the number of dummy word lines. The dummy transistor has the same structure as the memory cell transistor MT, and is a transistor which is not used to store data. Similarly, a dummy word line may be provided between the word line WL0 and select gate line SGS, and between the word line WL11 and select gate line SGDa.

[1-1-3] Structure of Memory Cell Array 10

An example of a structure of the memory cell array 10 in the first embodiment will be described below.

In the drawings to be referred to below, an X direction corresponds to the extending direction of the word line. WL, a Y direction corresponds to the extending direction of the bit line BL, and a Z direction corresponds to a direction perpendicular to the surface of a semiconductor substrate 20 on which the semiconductor memory device 1 is formed. Hatching is added to plan views as appropriate for clarification. The hatching added to the plan views is not necessarily related to the materials or properties of the constituent elements to which hatching is added. In cross-sectional views, constituent elements such as insulator layers (interlayer insulator films), interconnects and contacts are omitted as appropriate for clarification.

(Planar Layout of Memory Cell Array 10)

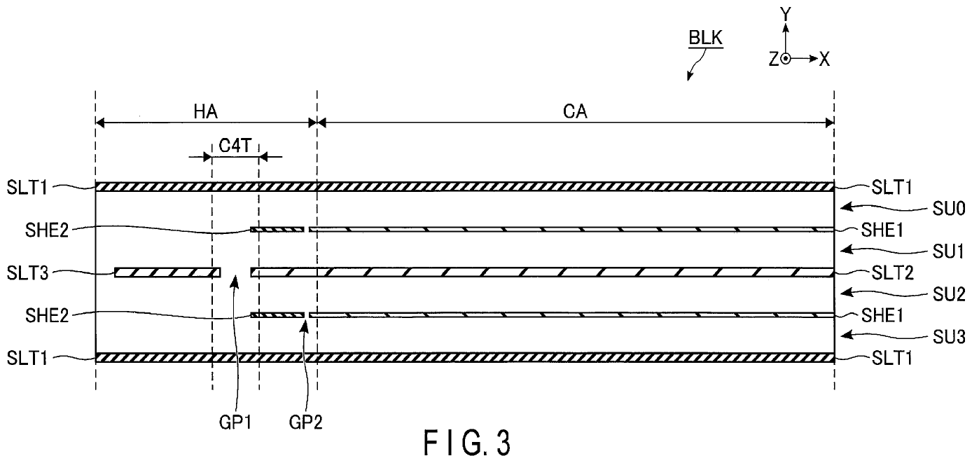

FIG. 3 illustrates an example of a planar layout of the memory cell array 10 included in the semiconductor memory device 1 according to the first embodiment. FIG. 3 illustrates, in an extracted manner, an area corresponding to one block BLK (i.e. string units SU0 to SU3). As illustrated in FIG. 3, the planar layout of the memory cell array 10 is divided into, for example, a cell area CA and a hookup area HA in the X direction. In addition, the memory cell array 10 includes slits SLT1, SLT2 and SLT3, and slits SHE1 and SHE2.

The cell area CA is an area where the NAND strings NS are formed. The hookup area HA is an area where contacts are formed for electrically connecting the word lines WL and select gate lines SGS and SGD, which are connected to the NAND strings NS, and the row decoder module 15. Further, the hookup area HA includes a through-contact area C4T which is provided to extend, for example, in the Y direction. The through-contact area C4T is an area where a contact is provided which penetrates stacked word lines WL and the like and electrically connects circuitry on the memory cell array 10 and circuitry under the memory cell array 10.

Each of the slits SLT1, SLT2 and SLT3 and slits SHE1 and SHE2 divides stacked interconnect layers. Further, each of the slits SLT1, SLT2 and SLT3 and slits SHE1 and SHE2 has such a structure that an insulator member is buried in the inside thereof, and insulates conductive layers which are provided in the same interconnect layer and are adjacent each other via the slit SLT.

Specifically, each of the slits SLT1, SLT2 and SLT3 divides, for example, a plurality of interconnect layers corresponding to the word lines WL0 to WL11, select gate lines SGDa, SGDb and SGDc, and select gate line SGS, respectively. Each of the slits SHE1 and SHE2 divides a plurality of interconnect layers corresponding to the select gate lines SGDa, SGDb and SGDc, respectively.

The slits SLT1 are provided to extend in the X direction, and are arranged in the Y direction. The slits SLT1 extend across the hookup area HA and cell area CA in the X direction. Each of the slits SLT2 and SLT3 is provided to extend in the X direction between two adjacent slits SLT1. The slit SLT2 extends from an end area in the hookup area HA, and extends across the cell area CA in the X direction. The slit SLT3 is disposed separated from the slit SLT2 in the hookup area HA.

In addition, the slits SLT2 and SLT3 are disposed, for example, such that the slits SLT2 and SLT3 are adjacent each other in the X direction. A gap portion GP1 is disposed between the slits SLT2 and SLT3. In other words, between the two slits SLT1 which are adjacent in the Y direction, a slit SLT extending from the hookup area HA to cell area CA is provided except for the gap portion GP1. The gap portion GP1 is disposed, for example, in the through-contact area C4T in the hookup area HA.

Between each slit SLT1 and the SLT 2 which are adjacent each other, for example, a pair of one slit SHE1 and one slit SHE2 is disposed. The slit SHE1 is provided to extend in the X direction and extends across the cell area CA in the X direction. The slit SHE2 is provided to extend in the X direction, and is disposed separated from the slit SHE1 in the hookup area HA.

Besides, the slits SHE1 and SHE2 are disposed, for example, such that the slits SHE1 and SHE2 are adjacent each other in the X direction. A gap portion GP2 is disposed between the slits SHE1 and SHE2. The gap portion GP2 is disposed near a boundary portion between the cell area CA and hookup area HA.

In the above-described planar layout of the memory cell array 10, each of the areas divided by the slits SLT1, SLT2 and SHE1 in the cell area CA corresponds to one string unit SU. Specifically, in this example, the string units SU0 to SU3 extending in the X direction are arranged in the Y direction. In addition, in the memory cell array 10, the layout illustrated in, for example, FIG. 3 is repeatedly arranged in the Y direction.

In the above-described planar layout of the memory cell array 10, the number of slits SLT2 and SLT3 disposed between the two adjacent slits SLT1 may be freely selected. The number of slits SHE1 and SHE2 disposed between the adjacent slits SLT1 and SLT2 may be freely selected. The number of string units SU between the two adjacent slits SLT1 varies based on the number of slits SLT2, SHE1 and SHE2 arranged between the two adjacent slits SLT1.

(Structure of Memory Cell. Array 10 in Cell Area CA)

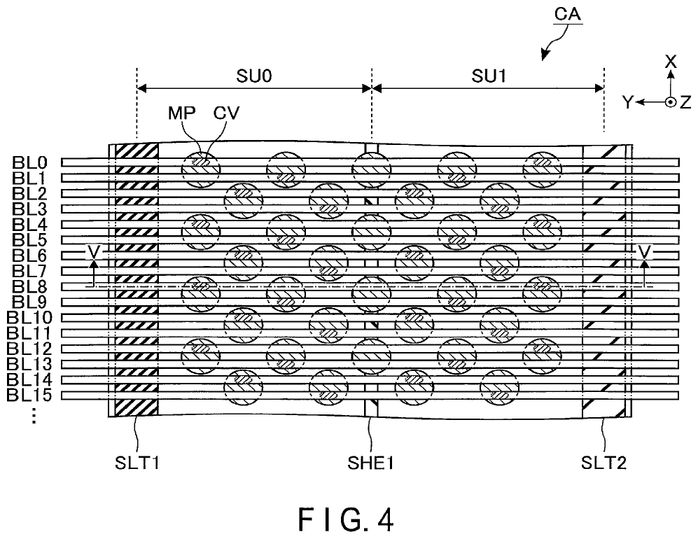

FIG. 4 illustrates an example of a detailed planar layout of the memory cell array 10 in the cell area CA of the semiconductor memory device 1 according to the first embodiment, by extracting an area corresponding to the string units SU0 and SU1. As illustrated in FIG. 4, in the cell area CA, the memory cell array 10 further includes a plurality of memory pillars MP, a plurality of contacts CV, and a plurality of bit lines BL.

Each of the memory pillars MP functions, for example, as one NAND string NS. The memory pillars MP are arranged in a staggering fashion in nine rows, for example, in an area between the adjacent slits SLT1 and SLT2. Memory pillars MP, which are arranged in the X direction in an intermediate portion between the adjacent slits SLT1 and SLT2, are disposed to overlap the slit SHE1. Specifically, the pillars MP include pillars MP which penetrate the slit SHE1 and are put in contact with adjacent select gate lines SGD.

The bit lines BL extend in the Y direction and are arranged in the X direction. Each bit line BL is disposed to overlap at least one memory pillar MP in each string unit SU. In this example, two bit lines BL are disposed to overlap each memory pillar MP. A contact CV is provided between one bit line BL of the bit lines BL overlapping the memory pillar MP, and the memory pillar MP. Each memory pillar MP is electrically connected to the corresponding bit line BL via the contact CV.

Note that the contact CV between the memory pillar MP, which overlaps the slit SHE1, and the bit line BL is omitted. In other words, the contact. CV between the memory pillar MP, which is in contact with two different select gate lines SGD, and the bit line BL is omitted. The numbers of memory pillars MP, slits SHE1 and the like between the adjacent slits SLT, and their dispositions are not limited to the structure described with reference to FIG. 4, and may be changed as appropriate.

The planar layout of the memory cell array 10 in the area corresponding to the string units SU2 and SU3 is similar to, for example, the planar layout of the memory cell array 10 in the area corresponding to the string units SU0 and SU1, so a description thereof is omitted.

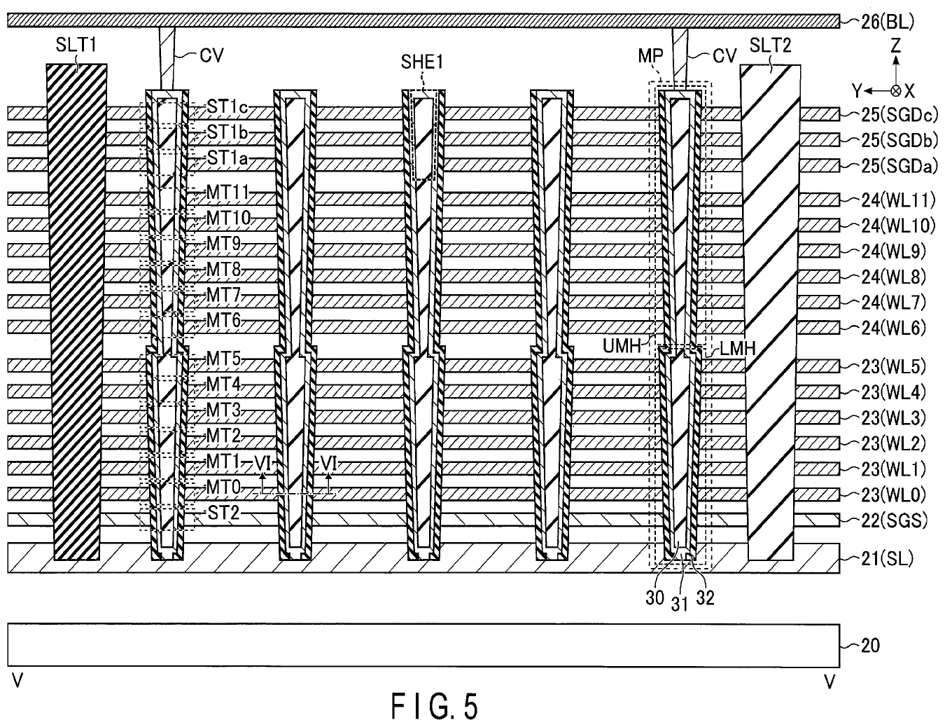

FIG. 5 is a cross-sectional view, taken along line V-V in FIG. 4, illustrating an example of a cross-sectional structure in the cell area CA of the memory cell array 10 included in the semiconductor memory device 1 according to the first embodiment. In addition, in FIG. 5, a part overlapping the slit SHE1 in the X direction is indicated by a broken line. As illustrated in FIG. 5, the memory cell array 10 further includes conductive layers 21 to 26. The conductive layers 21 to 26 are provided above the semiconductor substrate 20.

Specifically, the conductive layer 21 is provided above the semiconductor substrate 20 via an insulator layer. Although depiction is omitted, circuitry corresponding to, for example, the row decoder module 15, sense amplifier module 16 and the like is provided in the insulator layer between the semiconductor substrate 20 and conductive layer 21. The conductive layer 21 is formed, for example, in a plate shape extending along the XY plane, and is used as the source line SL. The conductive layer 21 includes, for example, silicon (Si).

The conductive layer 22 is provided above the conductive layer 21 via an insulator layer. The conductive layer 22 is formed, for example, in a plate shape extending along the XY plane, and is used as the select gate line SGS. The conductive layer 22 includes, for example, silicon.

Above the conductive layer 22, insulator layers and the conductive layers 23 are alternately stacked. Each conductive layer 23 is formed, for example, in a plate shape extending along the XY plane. For example, the stacked conductive layers 23 are used as word lines WL0 to WL5 in an order from the semiconductor substrate 20 side. The conductive layers 23 include, for example, tungsten (W).

Above the uppermost conductive layer 23, insulator layers and the conductive layers 24 are alternately stacked. Each conductive layer 24 is formed, for example, in a plate shape extending along the XY plane. For example, the stacked conductive layers 24 are used as word lines WL6 to WL11 in an order from the semiconductor substrate 20 side. The conductive layers 24 include, for example, tungsten.

Note that the thickness of the insulator layer between the uppermost conductive layer 23 and lowermost conductive layer 24 is greater than the thickness of the insulator layer between adjacent conductive layers 23, and is greater than the thickness of the insulator layer between adjacent conductive layers 24. In other words, the distance in the Z direction between the uppermost conductive layer 23 and lowermost conductive layer 24 is greater than the distance in the Z direction between adjacent conductive layers 23, and is greater than the distance in the Z direction between adjacent conductive layers 24.

Above the uppermost conductive layer 24, insulator layers and the conductive layers 25 are alternately stacked. Each conductive layer 25 is formed, for example, in a plate shape extending along the XY plane. For example, the stacked conductive layers 25 are used as select gate lines SGDa, SGDb and SGDc in an order from the semiconductor substrate 20 side. The conductive layers 25 include, for example, tungsten.

The conductive layer 26 is provided above the uppermost conductive layer 25 via an insulator layer. The conductive layer 26 is formed, for example, in a line shape extending in the Y direction, and is used as a bit line BL. Specifically, in an area not shown, a plurality of conductive layers 26 are arranged in the X direction. Each conductive layer 26 includes, for example, copper (Cu).

Each of the memory pillars MP is provided to extend in the Z direction, and penetrates the conductive layers 22 to 25. Each memory pillar MP includes a first portion formed in the inside of a memory hole LMH corresponding to lower-layer stacked interconnects, and a second portion formed in the inside of a memory hole UMH corresponding to upper-layer stacked interconnects.

The first portion corresponding to the memory hole LMH penetrates the conductive layers 22 and 23, and a bottom part of the first portion is in contact with the conductive layer 21. The second portion corresponding to the memory hole UMH is provided above the first portion corresponding to the memory hole LMH, and penetrates the conductive layers 24 and 25. For example, in each memory pillar MP, the outside diameter at an upper end of the first portion is greater than the outside diameter at a lower end of the second portion.

In addition, each memory pillar MP includes, for example, a core member 30, a semiconductor layer 31, and a stacked film 32. For example, each of the core member 30, semiconductor layer 31 and stacked film 32 is continuously provided between the first portion and second portion of the memory pillar MP.

Specifically, the core member 30 is provided to extend in the Z direction. For example, an upper end of the core member 30 is included in a layer which is higher than the uppermost conductive layer 25, and a lower end of the core member 30 is included in a layer in which the conductive layer 21 is provided. The semiconductor layer 31 includes, for example, a portion covering a side surface and a bottom surface of the core member 30, and a columnar portion extending in the Z direction at a bottom portion of the core member 30. For example, a bottom portion of the columnar portion of the semiconductor layer 31 is in contact with the conductive layer 21. The stacked film 32 covers a side surface and a bottom surface of the semiconductor layer 31, except for a portion where the columnar portion of the semiconductor layer 31 is provided. The core member 30 includes, for example, an insulator such as silicon oxide (SiO₂). The semiconductor layer 31 includes, for example, silicon.

The columnar contact CV is provided on a top surface of the semiconductor layer 31 in the memory pillar MP. In the area illustrated, contacts CV corresponding to two memory pillars MP among five memory pillars MP are depicted. In an area not illustrated, contacts CV are connected to the memory pillars MP which, in the illustrated area, do not overlap the slit SHE1 and are not connected to the contacts CV.

One conductive layer 26, i.e., one bit line BL, is in contact with a top surface of the contact CV. One contact CV is connected to one conductive layer 26 in each of spaces which are divided by the slits SLT1, SLT2 and SHE1 and by the memory pillar MP which is in contact with the slit SHE1. Specifically, for example, one memory pillar MP between the adjacent slit. SLT1 and SHE1, and one memory pillar MP between the adjacent slit SHE1 and SLT2, are electrically connected to each of the conductive layers 26.

The slit SLT is formed, for example, in a plate shape extending along the XZ plane, and divides the conductive layers 22 to 25. An upper end of the slit SLT is included in a layer between the uppermost conductive layer 25 and the conductive layer 26. A lower end of the slit SLT is included, for example, in the layer in which the conductive layer 21 is provided. The slit SLT includes, for example, an insulator such as silicon oxide.

The slit SHE1 is formed, for example, in a plate shape extending along the XZ plane, and divides the stacked conductive layers 25. An upper end of the slit SHE1 is included in the layer between the uppermost conductive layer 25 and the conductive layer 26. A lower end of the slit SHE1 is included, for example, in a layer between the uppermost conductive layer 24 and lowermost conductive layer 25. The slit SHE1 includes, for example, an insulator such as silicon oxide. For example, the upper end of the slit SHE1 and the upper end of the memory pillar MP are aligned with each other. However, the embodiment is not limited to this, and the upper end of the memory pillar MP may not be aligned with the upper end of the slit SLT, SHE.

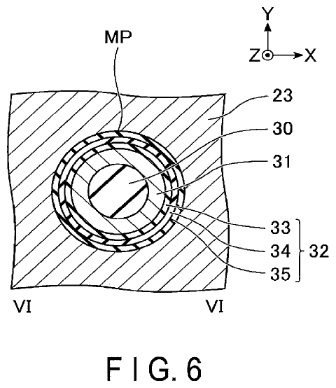

FIG. 6 is a cross-sectional view, taken along line VI-VI in FIG. 5, illustrating an example of a cross-sectional structure of the memory pillar MP in the semiconductor memory device 1 according to the first embodiment. More specifically, FIG. 6 illustrates a cross-sectional structure of the memory pillar MP in a layer which is parallel to the surface of the semiconductor substrate 20 and includes the conductive layer 23.

As illustrated in FIG. 6, in the layer including the conductive layer 23, the core member 30 is provided, for example, in a central part of the memory pillar MP. The semiconductor layer 31 surrounds the side surface of the core member 30. The stacked film 32 surrounds the side surface of the semiconductor layer 31. The stacked film 32 includes, for example, a tunnel insulator film 33, an insulator film 34 and a block insulator film 35.

The tunnel insulator film 33 surrounds the side surface of the semiconductor layer 31. The insulator film 34 surrounds a side surface of the tunnel insulator film 33. The block insulator film 35 surrounds a side surface of the insulator film 34. The conductive layer 23 surrounds a side surface of the block insulator film 35. Each of the tunnel insulator film 33 and block insulator film 35 includes, for example, silicon oxide. The insulator film 34 includes, for example, silicon nitride (SiN).

In the above-described structure of the memory pillar MP, an intersection portion between the memory pillar MP and conductive layer 22 functions as the select transistor ST2. Each of an intersection portion between the memory pillar MP and conductive layer 23 and an intersection portion between the memory pillar MP and conductive layer 24 functions as the memory cell transistor MT. An intersection portion between the memory pillar MP and conductive layer 25 functions as the select transistor ST1.

Specifically, the semiconductor layer 31 is used as a channel of each of the memory cell transistors MT0 to MT11 and select transistors ST1a, ST1b, ST1c and ST2. The insulator film 34 is used as a charge storage layer of the memory cell transistor MT. Thereby, each of the memory pillars MP functions as one NAND string NS.

(Structure of Memory Cell Array 10 in Hookup Area HA)

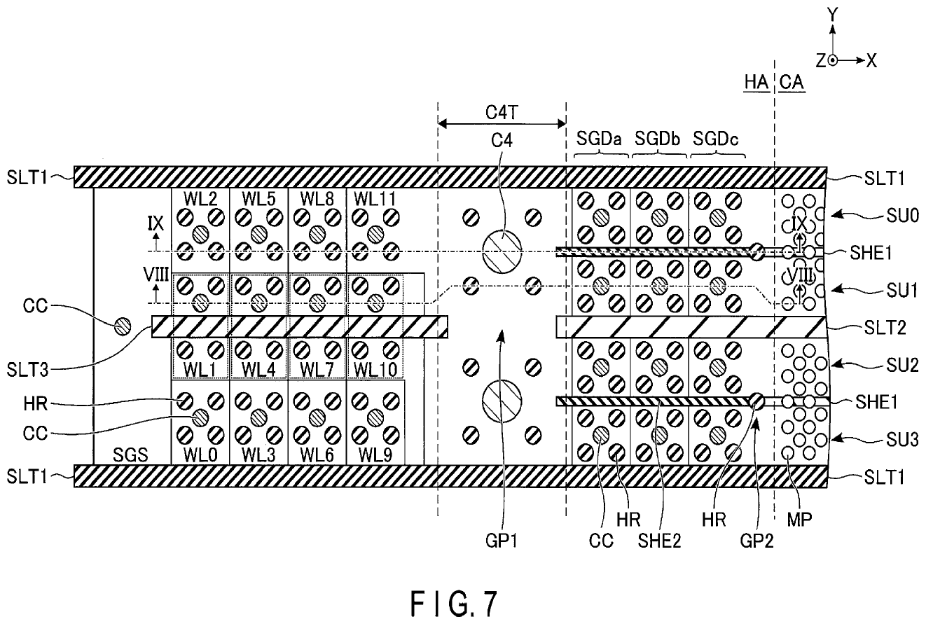

FIG. 7 illustrates an example of a detailed planar layout of the memory cell array 10 in the hookup area HA of the semiconductor memory device 1 according to the first embodiment, by extracting an area corresponding to one block BLK (i.e. string units SU0 to SU3). FIG. 7 also illustrates a part of the cell area CA near the hookup area HA.

As illustrated in FIG. 7, in the hookup area HA, end portions of the select gate line SGS, word lines WL0 to WL11 and select gate lines SGDa, SGDb and SGDc are provided in a stepped shape. In addition, in the hookup area HA, the memory cell array 10 further includes a plurality of contacts CC and C4, and a plurality of support pillars HR.

Specifically, each of the select gate line SGS, word lines WL0 to WL11 and select gate lines SGDa, SGDb and SGDc includes, in an end portion thereof, a terrace portion which does not overlap upper-layer interconnect layers (conductive layers). For example, the end portions of the word lines WL0 to WL11 are provided in a stepped shape of three rows, the stepped shape including two steps in the Y direction and a plurality of steps in the X direction. The end portions of the select gate lines SGDa, SGDb and SGDc are provided in a stepped shape in which steps are formed in the X direction. The select gate line SGS is led out from the area of the end portions of the word lines WL0 to WL11 which are formed in the stepped shape.

In this stepped structure of the stacked interconnects, the slit SLT3 is disposed, for example, in an intermediate portion between two adjacent slits SLT1, and extends across the terrace portions corresponding to the word lines WL1, WL4, WL7 and WL10 in the X direction. The slit SLT3 may or may not extend across the terrace portion of the select gate line SGS in the X direction. The slit SHE2 is disposed, for example, in an intermediate portion between the adjacent slits SLT1 and SLT2, and extends across the terrace portions corresponding to the select gate lines SGDa, SGDb and SGDc in the X direction.

Note that in this example, the word lines WL provided in the same layer in the same block BLK are short-circuited via the gap GP1. In other words, the word line WL, which is in contact with one slit SLT1 of the two adjacent slits SLT1, and the word line WL, which is in contact with the other slit SLT1, are electrically connected via the gap portion GP1.

The contacts CC are provided on the terrace portions of the select gate line SGS, word lines WL0 to WL11 and select gate lines SGDa, SGDb and SGDc. Each of the select gate line SGS, word lines WL0 to WL11 and select gate lines SGDa, SGDb and SGDc is electrically connected to the row decoder module 15 via the corresponding contact CC.

The contacts C4 are provided in the through-contact area C4T. The contacts C4 penetrate the stacked interconnect layers (e.g. source line SL, select gate line SGS and word lines WL) and are connected to an interconnect below the memory cell array 10. In addition, in this example, the contacts C4 are disposed to overlap the terrace portion of the word line WL11. The number of contacts C4 provided in the through-contact area C4T, and the dispositions of the contacts C4, may be changed as appropriate.

The support pillars HR are disposed as appropriate, for example, in the hookup area HA, in areas excluding the areas where the slits SLT1 and SLT2 are formed and areas where the contacts CC and C4 are formed. The support pillar HR has such a structure that an insulator member is buried in a hole extending in the Z direction, and the support pillar HR penetrates the stacked interconnect layers (e.g. word lines WL and select gate lines SGD). For example, a plurality of support pillars HR are disposed around the contact CC in the terrace portion of the word line WL0, and a plurality of support pillars HR are disposed around the contact C4 in the through-contact area C4T. The outside diameter of the support pillar HR is less than the outside diameter of the contact C4.

In addition, the support pillar HR is disposed in each of the gap portions GP2. Specifically, the support pillar HR is disposed, for example, between one slit SHE1 and one slit SHE2 which are adjacent in the X direction, and the support pillar HR couples the slits SHE1 and SHE2. Thereby, the select gate lines SGDa, SGDb and SGDc between the two adjacent slits SLT1 are separated by the paired slits SHE1 and SHE2 which are adjacent in the X direction and by the support pillar HR disposed between the slits SHE1 and SHE2.

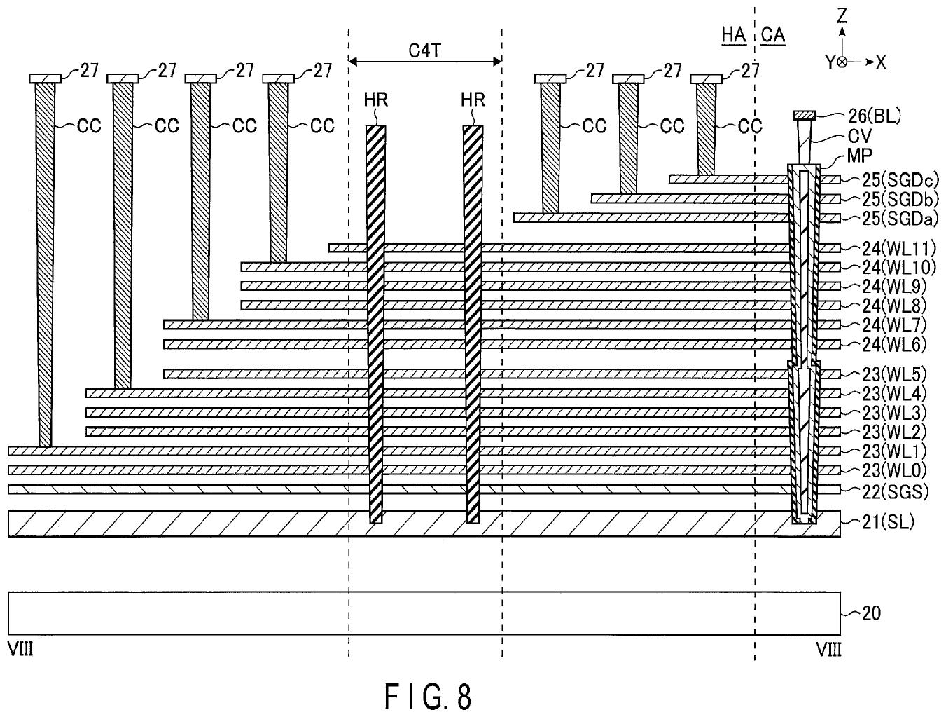

FIG. 8 is a cross-sectional view, taken along line VIII-VIII in FIG. 7, illustrating an example of a cross-sectional structure in the hookup area HA of the memory cell array 10 included in the semiconductor memory device 1 according to the first embodiment. In addition, FIG. 8 illustrates a cross-sectional area including the contacts CC. As illustrated in FIG. 8, in the hookup area HA, the end portions of the conductive layers corresponding to the word lines WL and select gate lines SGD are provided in a stepped shape. Besides, in the hookup area HA, the memory cell array 10 further includes a plurality of conductive layers 27.

The illustrated area includes a plurality of terrace portions corresponding to the word lines WL1, WL4, WL7 and WL10 and select gate lines SGDa, SGDb and SGDc. Further, one contact CC is provided on the terrace portion of each of the conductive layer 23 corresponding to the word line WL0, the conductive layer 23 corresponding to the word line WL4, the conductive layer 24 corresponding to the word line WL7, and the conductive layer 24 corresponding to the word line WL10, and each of the three conductive layers 25 corresponding to the select gate lines SGDa, SGDb and SGDc. One conductive layer 27 is provided on each contact CC and is electrically connected to each contact CC. Each conductive layer 27 is included, for example, in a layer above the conductive layer 26.

The support pillar HR is provided to extend in the Z direction, and penetrates, for example, the conductive layers 22 to 24 in the through-contact area C4T. An upper end of the support pillar HR is included, for example, in a layer between the conductive layer 26 and the upper end of the memory pillar MP. A lower end of the support pillar HR is included, for example, in the layer in which the conductive layer 21 is provided. Aside from this, the lower end of the support pillar HR reaches at least the conductive layer 22.

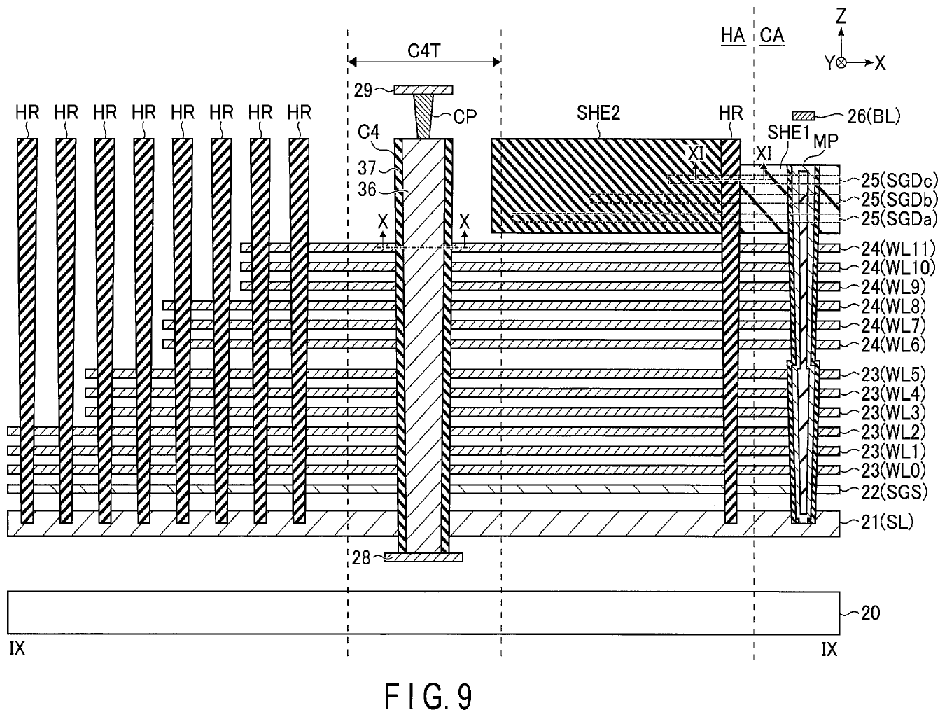

FIG. 9 is a cross-sectional view, taken along line IX-IX in FIG. 7, illustrating an example of a cross-sectional structure in the hookup area HA of the memory cell array 10 included in the semiconductor memory device 1 according to the first embodiment. In addition, FIG. 9 illustrates a cross-sectional area including support pillars HR between the slits SHE1 and SHE2, and indicates, by a broken line, a portion overlapping the three conductive layers 25 in the Y direction. As illustrated in FIG. 9, in the hookup area HA, the memory cell array 10 further includes conductive layers 28 and 29, and a contact CP.

The conductive layer 28 is an interconnect which is used in circuitry below the memory cell array 10. The conductive layer 29 is an interconnect which is used in circuitry above the memory cell array 10. The conductive layers 28 and 29 are electrically connected via the contact C4 on the conductive layer 28 and the contact CP on the contact C4.

The contact C4 is provided to extend in the Z direction, and penetrates, for example, the conductive layers 21 to 24 in the through-contact area C4T. An upper end of the contact C4 is aligned with, for example, an upper end of the support pillar HR. A lower end of the contact C4 is in contact with the conductive layer 28.

In addition, the contact C4 includes, for example, a conductive layer 36 and an insulator layer 37. The conductive layer 36 is provided in a columnar shape extending in the Z direction, and the contact CP is provided on the conductive layer 36. The insulator layer 37 covers a side surface of the conductive layer 36. The insulator layer 37 insulates the contact C4 from each conductive layer which the contact C4 penetrates.

The slit SHE2 is formed, for example, in a plate shape extending along the XZ plane, and divides the stacked conductive layers 25. An upper end of the slit SHE2 is included in the layer between the upper end of the memory pillar MP and the conductive layer 26. A lower end of the slit SHE2 is included, for example, in the layer between the uppermost conductive layer 24 and lowermost conductive layer 25. The slit SHE2 includes, for example, an insulator such as silicon oxide.

The support pillar HR, which is provided between the slits SHE1 and SHE2 that are adjacent in the X direction, that is, which is provided in the gap portion GP2, is in contact with each of the adjacent slits SHE1 and SHE2. Thereby, the three conductive layers 25 corresponding to the select gate lines SGDa, SGDb and SGDc, respectively, are separated by the slits SHE1 and SHE2, support pillar HR, and memory pillars MP overlapping the slit SHE1.

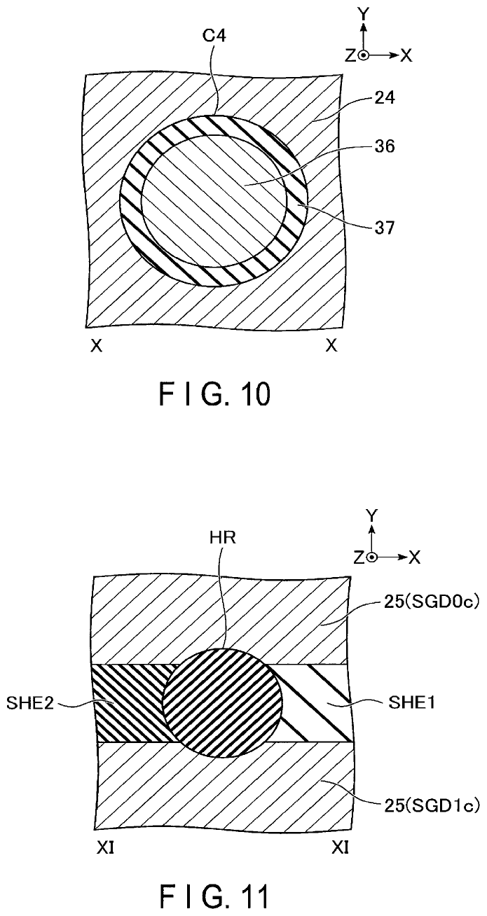

FIG. 10 is a cross-sectional view, taken along line X-X in FIG. 9, illustrating an example of a cross-sectional structure of the contact C4 in the semiconductor memory device 1 according to the first embodiment. More specifically, FIG. 10 illustrates a cross-sectional structure of the contact C4 in a layer which is parallel to the surface of the semiconductor substrate 20 and includes the conductive layer 24.

As illustrated in FIG. 10, in the layer including the conductive layer 24, the conductive layer 36 is provided, for example, in a central part of the contact C4. The insulator layer 37 surrounds a side surface of the conductive layer 36. The conductive layer 24 surrounds a side surface of the insulator layer 37.

FIG. 11 is a cross-sectional view, taken along line XI-XI in FIG. 9, illustrating an example of a cross-sectional structure of the support pillar HR in the semiconductor memory device 1 according to the first embodiment. More specifically, FIG. 11 illustrates a cross-sectional structure of the support pillar HR provided between the adjacent slits SHE1 and SHE2, in a layer which is parallel to the surface of the semiconductor substrate 20 and includes the conductive layer 25.

As illustrated in FIG. 11, the support pillar HR is composed of an insulator member. Aside from this, at least a side surface portion of the support pillar HR is composed of an insulator member. In the layer including the conductive layer 25, the support pillar HR between the slits SHE1 and SHE2 is in contact with, for example, an end portion of the slit SHE1, an end portion of the slit SHE2, a conductive layer 25 corresponding to a select gate line SGD0c, and a conductive layer 25 corresponding to a select gate line SGD1c. Specifically, the support pillar HR between the slits SHE1 and SHE2 is in contact with each of the two select gate lines SGD (conductive layers 25) which are provided in the same interconnect layer and are adjacent each other.

In the above-described structure of the memory cell array 10, the number of conductive layers 23 and the number of conductive layers 24 are designed based on the number of word lines WL corresponding to the memory holes LMH and UMH. A plurality of conductive layers 22 provided in a plurality of layers may be assigned to the select gate line SGS. When the select gate line SGS is provided in a plurality of layers, a conductor different from the conductive layer 22 may be used. The number of conductive layers 25 used as the select gate lines SGD may be freely selected.

Each of the contacts CP and CV may be configured such that a plurality of contacts are coupled in the Z direction. An interconnect layer may be inserted between the contacts coupled in the Z direction. The conductive layers 28 and 29 may pass through the area illustrated in FIG. 8. Similarly, the conductive layer 27 may pass through the area illustrated in FIG. 9.

In the present specification, the case in which the hookup area HA includes the through-contact area C4T is described by way of example. However, the embodiment is not limited to this. For example, the through-contact area C4T may be disposed in some other region, or a plurality of through-contact areas C4T may be provided. The through-contact area C4T may be inserted in the cell area CA. The contact C4 disposed in the cell area CA penetrates the source line SL, select gate lines SGS and SGD, and word lines WL.

[1-2] Manufacturing Method of Semiconductor Memory Device 1

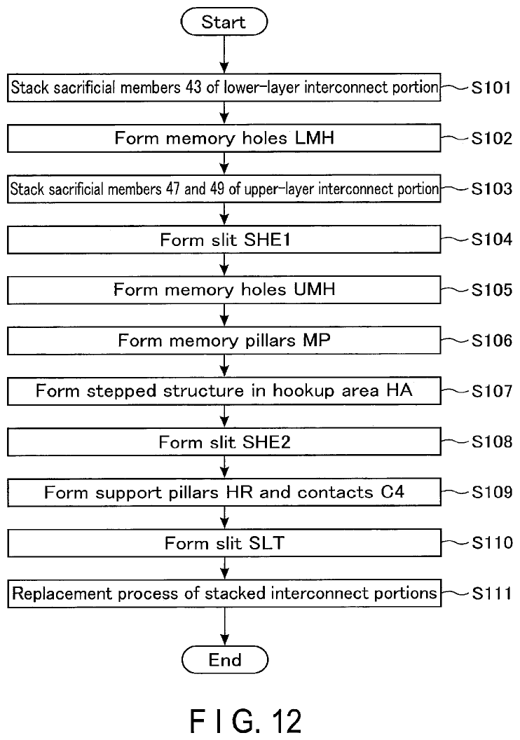

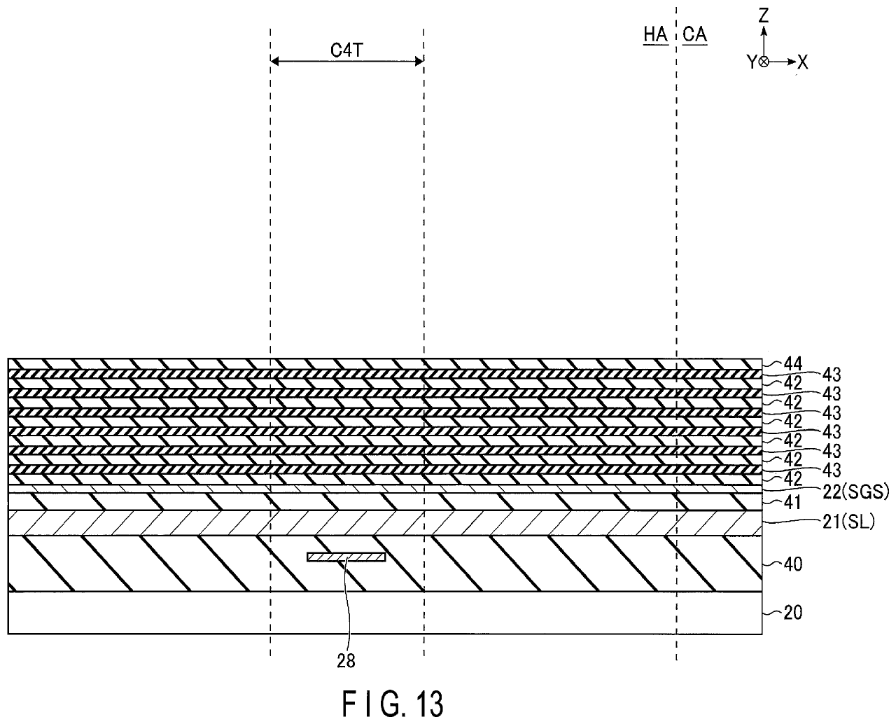

Hereinafter, referring to FIG. 12 as needed, a description will be given of an example of serial manufacturing steps relating to the formation of a stacked interconnect structure in the memory cell array 10 in the semiconductor memory device 1 according to the first embodiment. FIG. 12 is a flowchart illustrating an example of a manufacturing method of the semiconductor memory device 1 according to the first embodiment. Each of FIG. 13 to FIG. 29 illustrates an example of a planar layout or a cross-sectional structure during the manufacture of the semiconductor memory device 1 according to the first embodiment. In the following description of the manufacturing method, plan views to be referred to correspond to the area illustrated in FIG. 7, and cross-sectional views to be referred to correspond to the area illustrated in FIG. 9.

To begin with, by a process of step S101, sacrificial members 43 of a lower-layer interconnect portion are stacked as illustrated in FIG. 13. The sacrificial members 43 of the lower-layer interconnect portion correspond to stacked interconnects which a memory hole LMH that is formed in a later step penetrates. In the present step, an insulator layer 40 including a conducive layer 28, a conductive layer 21, an insulator layer 41, and a conductive layer 22 are successively stacked on a semiconductor substrate 20. Although not illustrated, circuitry corresponding to the row decoder module 15, sense amplifier module 16 and the like is formed in the insulator layer 40. Thereafter, insulator layers 42 and sacrificial members 43 are alternately stacked on the conductive layer 22. An insulator layer 44 is formed on the uppermost sacrificial member 43.

The conductive layer 21 is used as a source line SL. The conductive layer 21 includes, for example, silicon (Si). The conductive layer 22 is used as a select gate line SGS. The conductive layer 22 includes, for example, silicon. Each of the insulator layers 41, 42 and 44 includes, for example, silicon oxide (SiO₂). For example, the number of layers, in which the sacrificial layers 43 are formed, corresponds to the number of word lines WL which a memory hole LMH penetrates. The sacrificial member 43 includes, for example, silicon nitride (SiN).

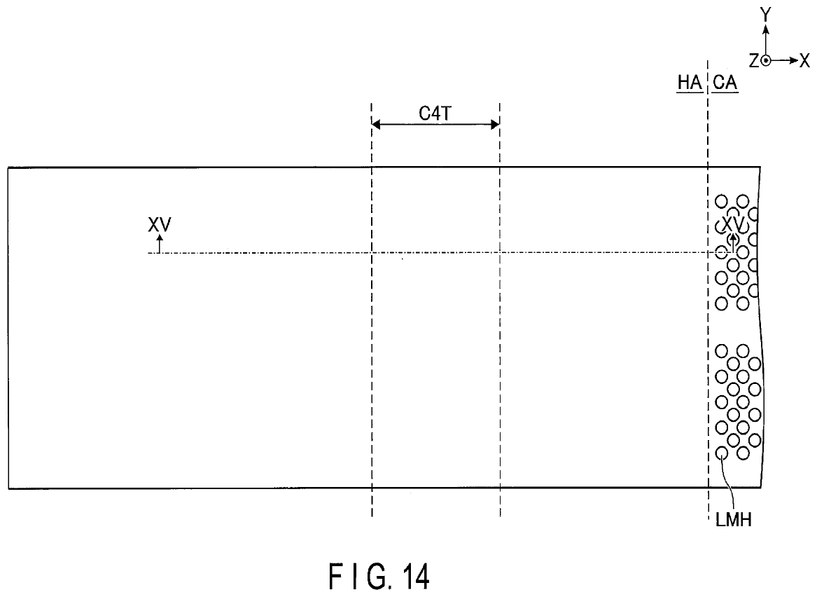

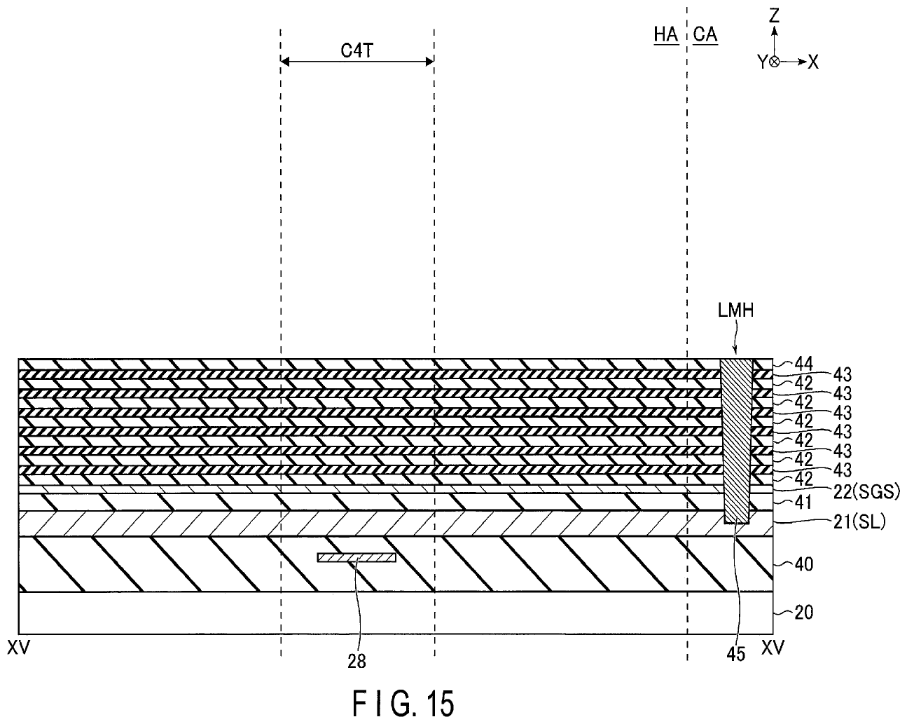

Next, by a process of step S102, memory holes LMH are formed as illustrated in FIG. 14 and FIG. 15. Specifically, a mask with an opening corresponding to the memory holes LMH is first formed by photolithography or the like. Then, the memory holes LMH are formed by anisotropic etching using the formed mask. In plan view, the memory holes LMH formed in this step are disposed, for example, in a staggering fashion. Then, a sacrificial member 45 is buried in the inside of the memory holes LMH.

The memory holes LMH formed in this step penetrates the insulator layers 41, 42 and 44 and sacrificial layers 43. A bottom portion of the memory hole LMH stops, for example, in the conductive layer 21. The anisotropic etching in this step is, for example, RIE (Reactive Ion Etching).

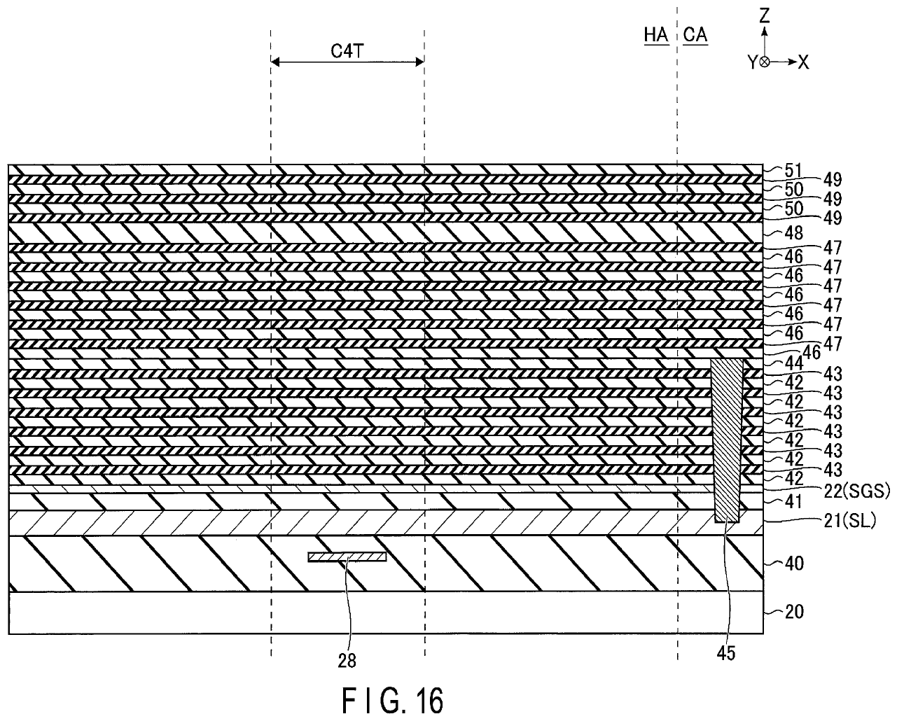

Next, by a process of step S103, sacrificial members 47 and 49 of an upper-layer interconnect portion are stacked as illustrated in FIG. 16. The sacrificial members 47 and 49 of the upper-layer interconnect portion correspond to stacked interconnects which memory holes UMH penetrates by a later step. In the present step, to begin with, insulator layers 46 and sacrificial members 47 are alternately stacked on the insulator layer 44 and sacrificial member 45, and an insulator layer 48 is formed on the uppermost sacrificial member 47. Then, sacrificial members 49 and insulator layers 50 are alternately stacked on the insulator layer 48, and an insulator layer 51 is formed on the uppermost sacrificial member 49.

Each of the insulator layers 46, 48, 50 and 51 includes, for example, silicon oxide. For example, the number of layers, in which the sacrificial layers 47 are formed, corresponds to the number of word lines WL which a memory holes UMH penetrates. The number of layers, in which the sacrificial layers 49 are formed, corresponds to the number of select gate lines SGD which the memory holes UMH penetrates. The sacrificial members 47 and 49 are formed of, for example, the same material as the sacrificial members 43, and include silicon nitride.

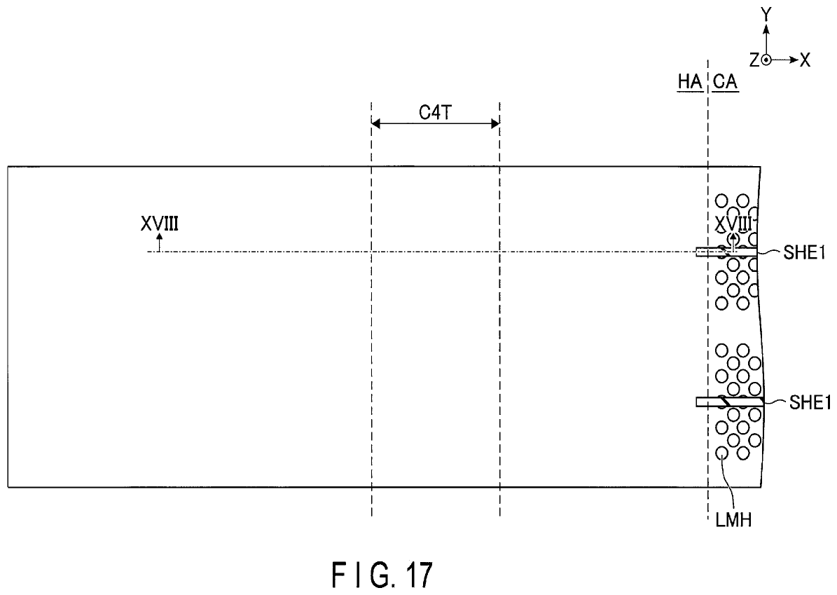

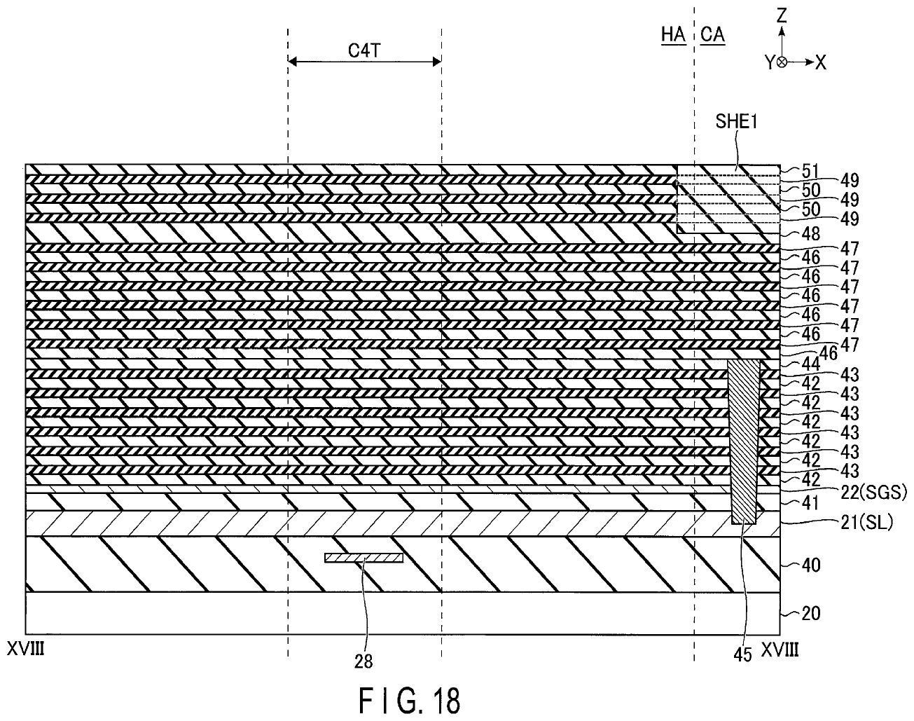

Next, by a process of step S104, a slit SHE1 is formed as illustrated in FIG. 17 and FIG. 18. Specifically, a mask with an opening corresponding to the slit SHE1 is first formed by photolithography or the like. Then, the slit SHE1 is formed by anisotropic etching using the formed mask. Subsequently, an insulator is buried in the inside of the slit SHE1.

The slit SHE1 formed in this step divides the sacrificial members 49 stacked in the cell area. CA. A bottom portion of the slit SHE1 stops, for example, in the layer in which the insulator layer 48 is formed. The anisotropic etching in this step is, for example, RIE.

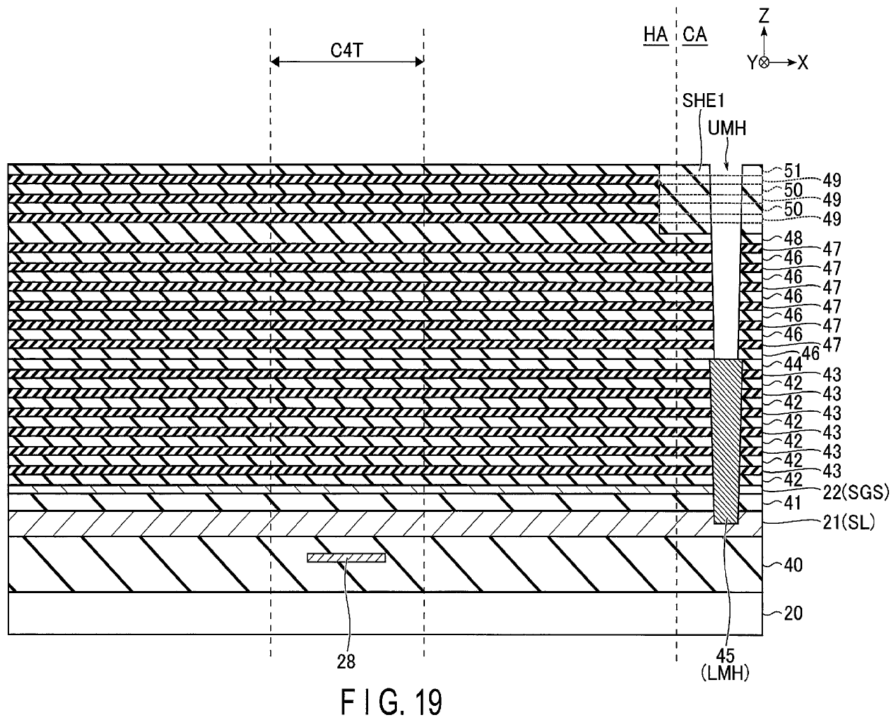

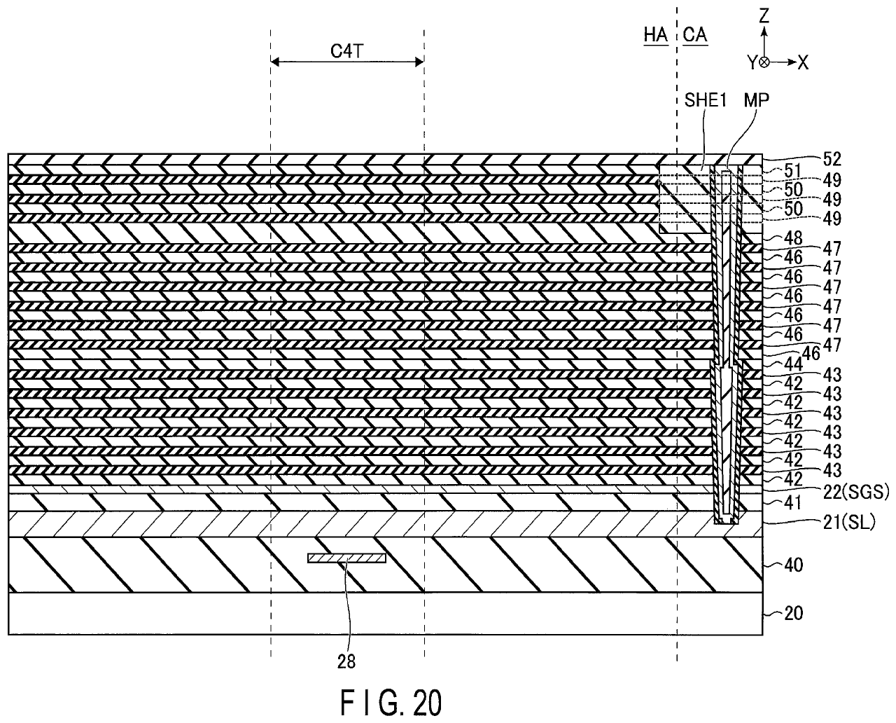

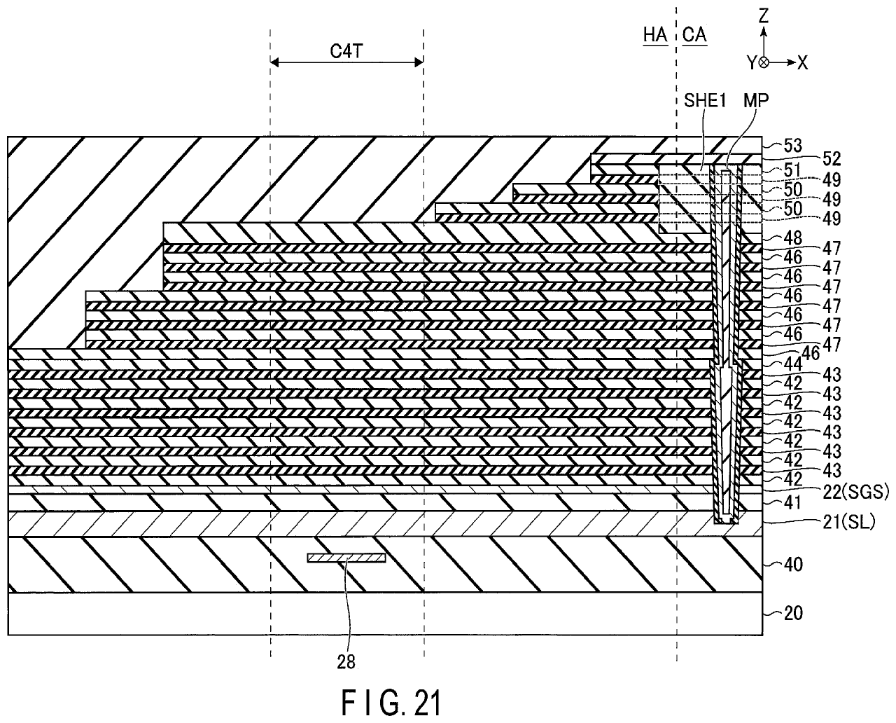

Next, by a process of step S105, memory holes UMH are formed as illustrated in FIG. 19. Specifically, a mask with an opening in an area corresponding to the memory holes UMH, i.e. an area overlapping the memory holes LMH in plan view, is first formed by photolithography or the like. Then, the memory holes UMH is formed by anisotropic etching using the formed mask.

The memory holes UMH formed in this step penetrates the insulator layers 46, 48, 50 and 51. At a bottom portion of the memory hole UMH, a part of the sacrificial member 45 in the memory hole LMH is exposed. Note that in the present step, the memory hole UMH overlapping the slit SHE1 removes a part of the insulator in the slit SHE1. The anisotropic etching in this step is, for example, RIE.

Next, by a process of step S106, memory pillars MP are formed as illustrated in FIG. 20. Specifically, the sacrificial member 45 in the memory hole LMH is first removed via the memory hole UMH. Then, memory holes, which opens in the shape of the memory pillar MP, is formed. Then, a block insulator film 35, an insulator film 34 and a tunnel insulator film 33 are successively formed on a side surface and bottom surface of the memory hole and on a top surface of the insulator layer 51.

Thereafter, a part of the block insulator film 35, insulator film 34 and tunnel insulator film 33 at a memory hole bottom portion is removed, and a part of the conductive layer 21 is exposed at the memory hole bottom portion. Subsequently, a semiconductor layer 31 and a core member 30 are successively formed, and the core member 30 is buried in the memory hole. Then, a part of the core member 30 formed at a memory hole top portion is removed, and a semiconductor material is buried in the space corresponding to the removed part of the core member 30.

In the present step, the block insulator film 35, insulator film 34, tunnel insulator film 33 and semiconductor layer 31, which remain in a layer above the insulator layer 51, are removed by, for example, CMP (Chemical Mechanical Polishing). Thereby, a structure corresponding to the memory pillar MP is formed in the memory hole. After the memory pillar MP is formed, an insulator layer 52, for example, is formed on a top surface of the memory pillar MP and on the insulator layer 51. The insulator layer 52 includes, for example, silicon oxide.

Next, by a process of step S107, a stepped structure in the hookup area HA is formed as illustrated in FIG. 21. Specifically, a mask covering, for example, a part of a stepped area in the hookup area HA is first formed by photolithography or the like. Then, Y-directional steps are formed in the sacrificial members 43 and 47 provided in the hookup area HA, by a combination of the anisotropic etching using the formed mask and a slimming process of the mask.

Subsequently, like the formation of the Y-directional steps, the formation of a mask covering a part of the stepped area in the hookup area HA, etching and slimming process are performed, and X-directional steps are formed in the sacrificial members 43, 47 and 49 provided in the hookup area HA. Thereby, a stepped structure similar to the stepped structure of interconnect layers described with reference to FIG. 7 to FIG. 9 is formed in the stacked sacrificial members 43, 47 and 49. Thereafter, an insulator layer 53 is formed in a manner to fill the space formed on the stepped structure in the hookup area HA, and a top surface of the insulator layer 53 is planarized by CMP or the like.

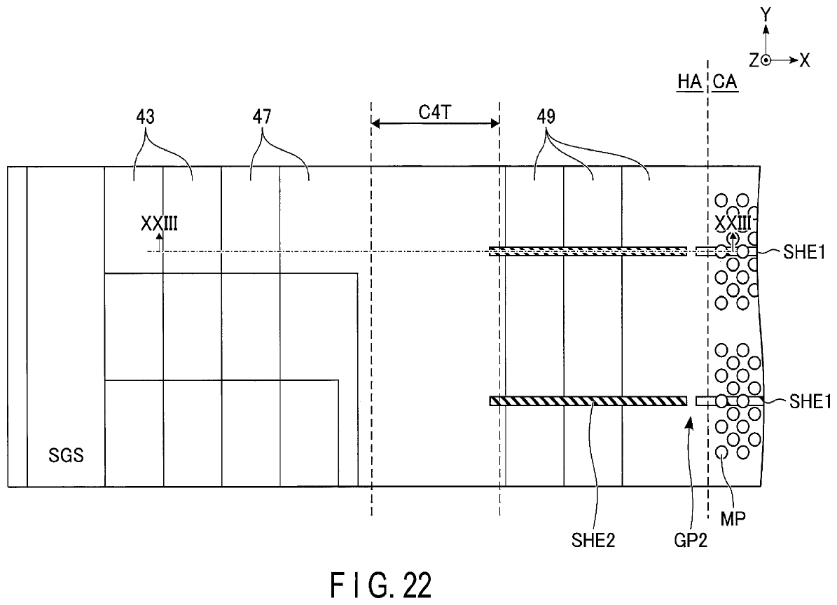

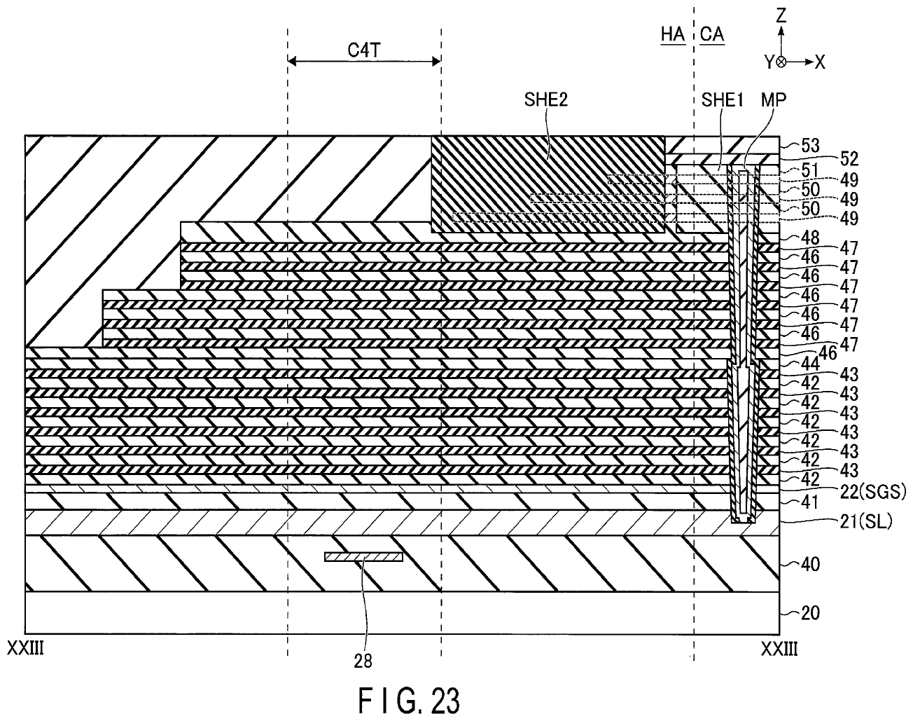

Next, by a process of step S108, a slit SHE2 is formed as illustrated in FIG. 22 and FIG. 23. Specifically, a mask with an opening in an area corresponding to the slit SHE2 is first formed by photolithography or the like. Then, the slit SHE2 is formed by anisotropic etching using the formed mask. Further, an insulator is buried in the slit SHE2.

The slit SHE2 formed in the present step divides the sacrificial members 49 stacked in the hookup area HA. A bottom portion of the slit SHE2 stops, for example, in the layer in which the insulator layer 48 is formed. The anisotropic etching in this step is, for example, RIE.

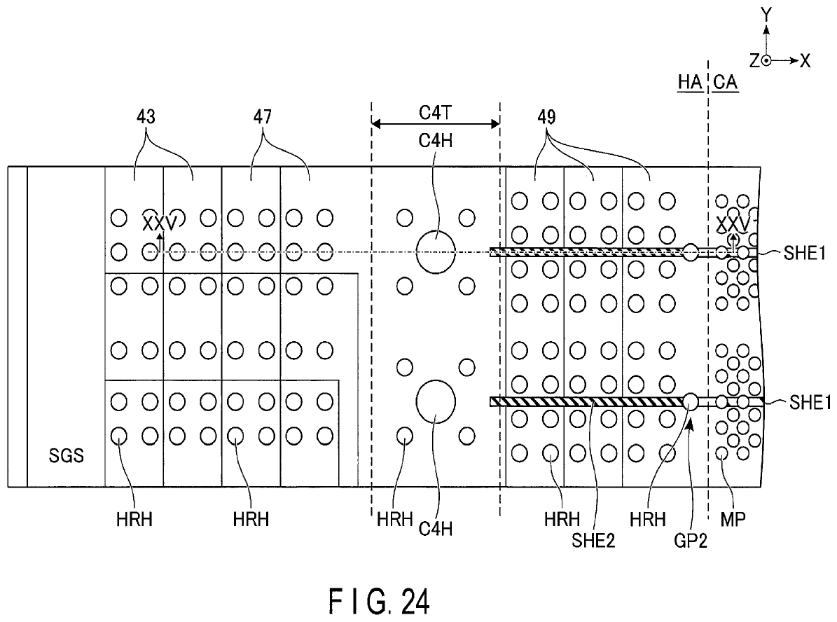

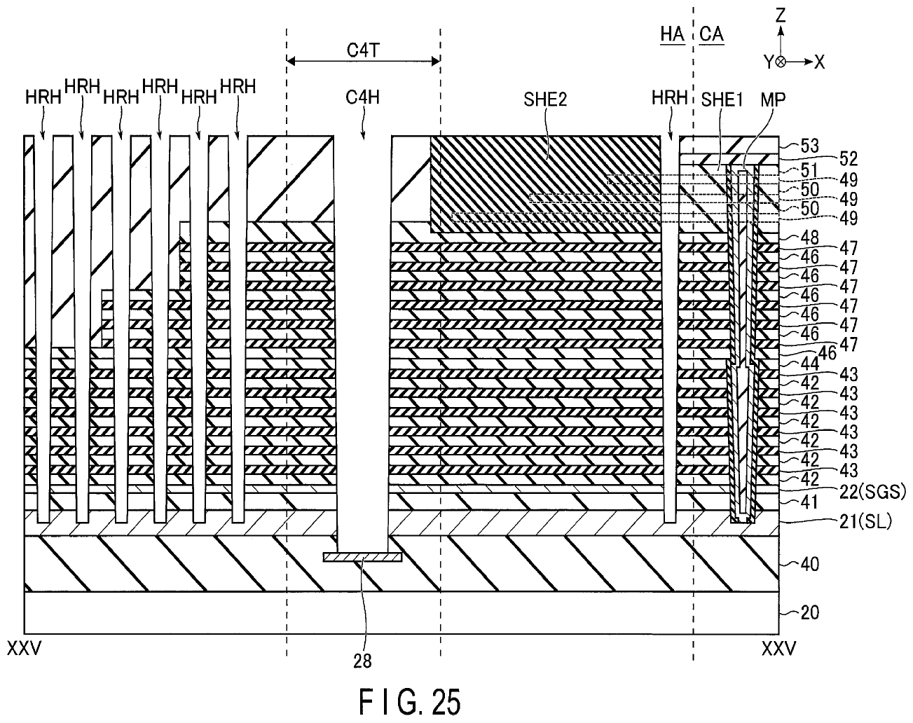

Next, by a process of step S109, support pillars HR and contacts C4 are formed. Specifically, a mask with openings in areas corresponding to the support pillars HR and contacts C4 is first formed by lithography or the like. Then, holes HRH and C4H are formed as illustrated in FIG. 24 and FIG. 25, by anisotropic etching using the formed mask. The hole HRH corresponds to an area where the support pillar HR is formed. The hole C4H corresponds to an area where the contact C4 is formed. A plurality of holes HRH formed in the first embodiment include a hole HRH which is provided to overlap end portions of the slits SHE1 and SHE2 that are adjacent each other in the X direction.

The hole HRH formed in this step penetrates, for example, the conductive layer 22, insulator layers 41, 42, 44, 46, 48, 50, 51, 52 and 53 and sacrificial members 43, 47 and 49. A bottom portion of the hole HRH stops, for example, in the layer in which the conductive layer 21 is provided. The hole C4H formed in this step penetrates, for example, the conductive layers 21 and 22, insulator layers 41, 42, 44, 46, 48 and 53 and sacrificial members 43 and 47. At a bottom portion of the hole C4H, for example, a surface of the conductive layer 28 is exposed.

Thereafter, an insulator layer 37 is formed on a side surface and bottom surface of the hole C4H and in the inside of the hole HRH, and the insulator layer 37 is buried in the inside of the hole HRH. In addition, a part of the insulator layer 37 formed in the bottom portion of the hole C4H is removed by etch-back, and subsequently a conductive layer 36 is buried in the inside of the hole C4H. The conductive layer 36 formed outside the hole C4H is removed by, for example, CMP.

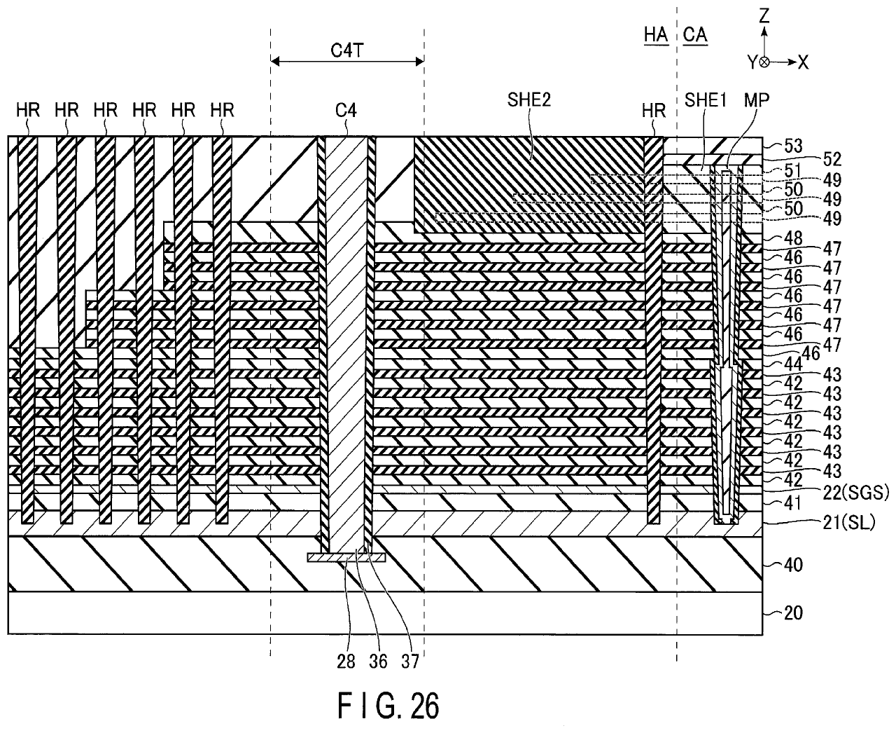

Thereby, as illustrated in FIG. 26, support pillars HR and contacts C4 are formed. In this example, the case was exemplarily described in which the surface of the conductive layer 28 is exposed when the holes HRH and C4H are processed. However, the embodiment is not limited to this example. For example, the process of exposing the surface of the conductive layer 28 at the bottom portion of the hole C4H may be executed by etching which is different from the etching for simultaneously forming the holes HRH and C4H.

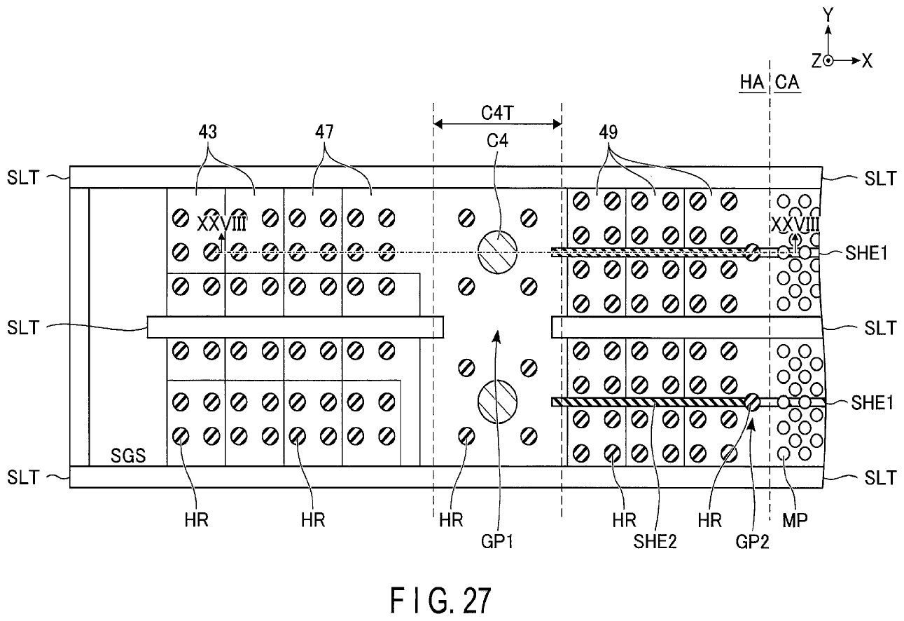

Next, by a process of step S110, slits SLT are formed as illustrated in FIG. 27. Specifically, a mask with openings in areas corresponding to slits SLT1, SLT2 and SLT3 is first formed by photolithography or the like. Then, the slits SLT are formed by anisotropic etching using the formed mask.

The slit SLT formed in this step divides the insulator layers 41, 42, 44, 46, 48, 50, 51, 52 and 53 and sacrificial layers 43, 47 and 49. A bottom portion of the slit SLT stops, for example, in the layer in which the conductive layer 21 is provided. Note that in this example, the bottom portion of the slit SLT reaches at least the layer in which the insulator layer 41 is formed. The anisotropic etching in this step is, for example, RIE.

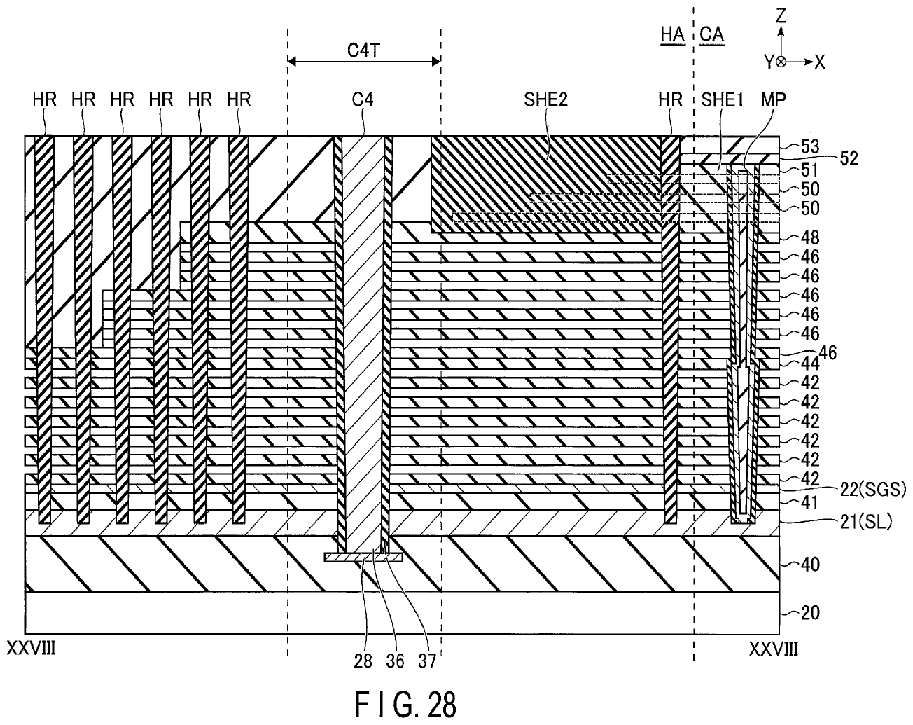

Next, by a process of step S111, a replacement process of stacked interconnects is executed. Specifically, to begin with, as illustrated in FIG. 28, the sacrificial layers 43, 47 and 49 are selectively removed by, for example, wet etching by hot phosphoric acid. A structure in which the sacrificial layers 43, 47 and 49 are removed keeps its three-dimensional structure by the memory pillars MP, support pillars HR, contacts C4 and the like.

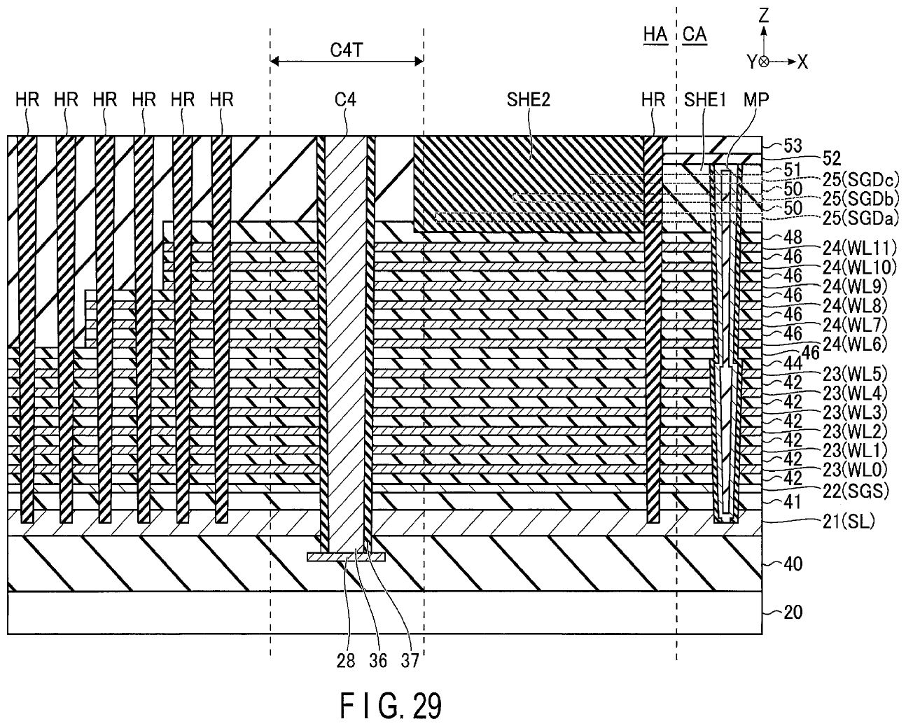

Then, as illustrated in FIG. 29, conductors are buried in the spaces from which the sacrificial layers 43, 47 and 49 are removed. For example, CVD is used for the formation of the conductors in this step. Thereafter, by an etch-back process, the conductors formed in the inside of the slit SLT and on the top surface of the insulator layer 53 are removed. In the present step, the conductors formed in adjacent interconnect layers are separated at least in the slit SLT.

Thereby, conductive layers 23 corresponding to the word lines WL0 to WL5, conductive layers 24 corresponding to the word lines WL6 to WL11, and conductive layers 25 corresponding to the select gate lines SGDa, SGDb and SGDc are formed. The conductive layers 23 to 25 formed in the present step may include barrier metals. In this case, in the formation of conductors after the removal of the sacrificial members 43, 47 and 49, for example, a film of titanium nitride is formed as a barrier metal, and then tungsten is formed. The slit SLT used in this step is filled with an insulator, after stacked interconnects are formed.

By the above-described manufacturing steps of the semiconductor device 1 according to the first embodiment, the memory pillars MP, and the source line SL, word lines WL and select gate lines SGDa, SGDb, SGDc and SGS, which are connected to the memory pillars MP, are formed. Note that the above-described manufacturing steps are merely examples, and other processes may be inserted between the respective manufacturing steps.

[1-3] Advantageous Effects of the First Embodiment

According to the above-described semiconductor memory device 1 of the first embodiment, the yield of semiconductor memory devices 1 can be improved. Hereinafter, the advantageous effects of the semiconductor memory device 1 according to the first embodiment will be described in detail.

In a semiconductor memory device in which memory cells are three-dimensionally stacked, plate-shaped interconnects that are used, for example, as word lines WL, are stacked. In addition, a multilayer film for enabling a function as a memory cell transistor MT is formed in a memory pillar MP which penetrates the stacked interconnects. Further, like the word lines WL, plate-shaped select gate lines SGD, penetrated by the memory pillar MP, are formed. In the semiconductor memory device, the select gate line SGD in an identical interconnect layer is divided as appropriate and insulated by a slit SHE, and thereby an operation on a page-by-page basis can be implemented.

One conceivable method of increasing a storage capacity per unit area of this type of semiconductor memory device is a method of increasing the number of stacked layers of word lines WL, that is, a method of increasing the number of stacked layers of memory cell transistors MT. If the number of stacked layers of word lines WL is increased, the difficulty in processing the hole for forming the memory pillar MP increases. Thus, it is also conceivable to perform, in two stages, the hole processing for forming the memory pillar MP.

For example, when the hole processing for forming the memory pillar MP is performed in two stages, sacrificial members 43 corresponding to a lower-layer interconnect portion are first stacked, a memory hole LMH is formed, and a sacrificial member is buried in the inside of the memory hole LMH. Then, sacrificial members 47 corresponding to an upper-layer interconnect portion are stacked, and sacrificial members 49 corresponding to select gate lines SGD are divided by the slit SHE. Subsequently, the processing for a stepped structure in the hookup area HA is performed, and the formation of a memory hole UMH and the formation of the memory pillar MP are carried out.

In this manufacturing method of the semiconductor memory device, it is possible that the stacked-layer structure of the insulator layers and sacrificial members in the cell area CA is distorted by an insulator film which is buried in the area where the processing for the stepped structure in the hookup area HA was performed. If the stacked-layer structure in the cell area CA is distorted, it is possible that a misalignment occurs between the memory hole LMH that penetrates the lower-layer interconnect portion, and the memory hole UMH that penetrates the upper-layer interconnect portion, resulting in a defect due to the memory pillar MP. It is thus preferable that the processing for the stepped structure in the hookup area HA is performed after the formation of the memory pillar MP.

However, when the processing for the stepped structure is performed after the formation of the memory pillar MP, there is concern that, at the time of performing the processing for the stepped structure, a part of the sacrificial members 49 corresponding to the select gate lines SGD is removed via the part of the slit SHE formed in the hookup area HA. If such a change in shape occurs in the sacrificial members 49 in the hookup area HA, a variance occurs among the shapes of end portions of conductive layers 25 corresponding to the select gate lines SGD, and a defect may occur due to connections between the select gate lines SGD and contacts CC.

In addition, in the planar layout in the cell area CA, the disposition of the slit SHE overlaps, for example, the disposition of the memory pillar MP. Since a multilayer film is provided in the memory pillar MP, it is difficult to process the slit SHE after the formation of the memory pillar MP. It is thus preferable that the slit SHE in the cell area CA is formed before the formation of the memory pillar MP.

Taking the above into account, in the manufacturing method of the semiconductor memory device 1 according to the first embodiment, the slit SHE1 in the cell area CA and the slit SHE2 in the hookup area HA are formed in different manufacturing steps. In addition, in the manufacturing method of the semiconductor memory device 1 according to the first embodiment, the processing for the stepped structure in the hookup area HA is performed after the formation of the slit SHE1 and before the formation of the slit SHE2.

Specifically, in the manufacturing method of the semiconductor memory device 1 according to the first embodiment, the sacrificial members 49 in the cell area CA are first divided by the slit SHE1, and then the memory pillar MP is formed. Further, the processing for the stepped structure in the hookup area HA is executed, and then the sacrificial members 49 in the hookup area HA are divided by the slit SHE2.

In addition, the semiconductor memory device 1 according to the first embodiment includes the gap portion GP2 between the slits SHE1 and SHE2, in order to avoid an overlap between the adjacent slits SHE1 and SHE2. In this manner, if the gap portion GP2 is provided at the time point of designing the planar layout of the memory cell array 10, an overlap between the adjacent slits SHE1 and SHE2 due to the misalignment at the time of manufacture is suppressed. In the area of the gap portion GP2, the sacrificial member 49 corresponding to the select gate line SGD remains in the continuous state. However, the support pillar HR, which is subsequently formed, is provided in a manner to overlap the gap GP2.

As a result, in the semiconductor memory device 1 according to the first embodiment, such a structure is formed that the adjacent sacrificial members 49 in the same interconnect layer are separated by the slits SHE1 and SHE2, support pillar HR, and memory pillars MP penetrating the slit SHE1. Specifically, in the semiconductor memory device 1 according to the first embodiment, the adjacent select gate lines SGD (conductive layers 25) can be insulated by the slit SHE1 in the cell area CA, the slit SHE2 in the hookup area HA, the support pillar HR between the slits SHE1 and SHE2, and the memory pillars MP penetrating the slit SHE1.

As described above, in the manufacturing method of the semiconductor memory device 1 according to the first embodiment, the slit SHE2 is formed after the formation of the stepped structure in the hookup area HA. Thus, a change in shape of the sacrificial members 49 in the hookup area HA at the time of the processing for the stepped structure is suppressed. Furthermore, in the manufacturing method of the semiconductor memory device 1 according to the first embodiment, since the processing for the stepped structure in the hookup area HA is performed after the formation of the memory pillars MP, the alignment at the time of forming the memory hole UMH is not affected by a distortion after the processing for the stepped structure in the hookup area HA.

Therefore, the semiconductor memory device 1 according to the first embodiment can suppress the occurrence of a defect due to the contacts CC of the select gate lines SGD, and the occurrence of a defect due to a misalignment between the memory holes LMH and UMH. In short, the semiconductor memory device 1 according to the first embodiment can improve the yield of semiconductor memory devices 1.

### [2] Second Embodiment

A semiconductor memory device 1 according to a second embodiment relates to a modification of the manufacturing method of the semiconductor memory device 1 described in the first embodiment, and a stepped structure corresponding to the lower-layer interconnect portion and a stepped structure corresponding to the upper-layer interconnect portion are formed in different manufacturing steps. Hereinafter, the semiconductor memory device 1 according to the second embodiment will be described with respect to different points from the first embodiment.

[2-1] Manufacturing Method of Semiconductor Memory Device 1

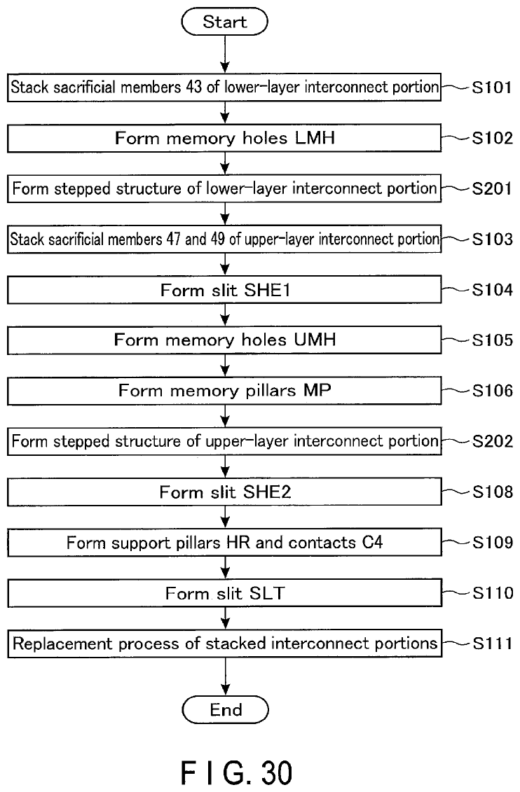

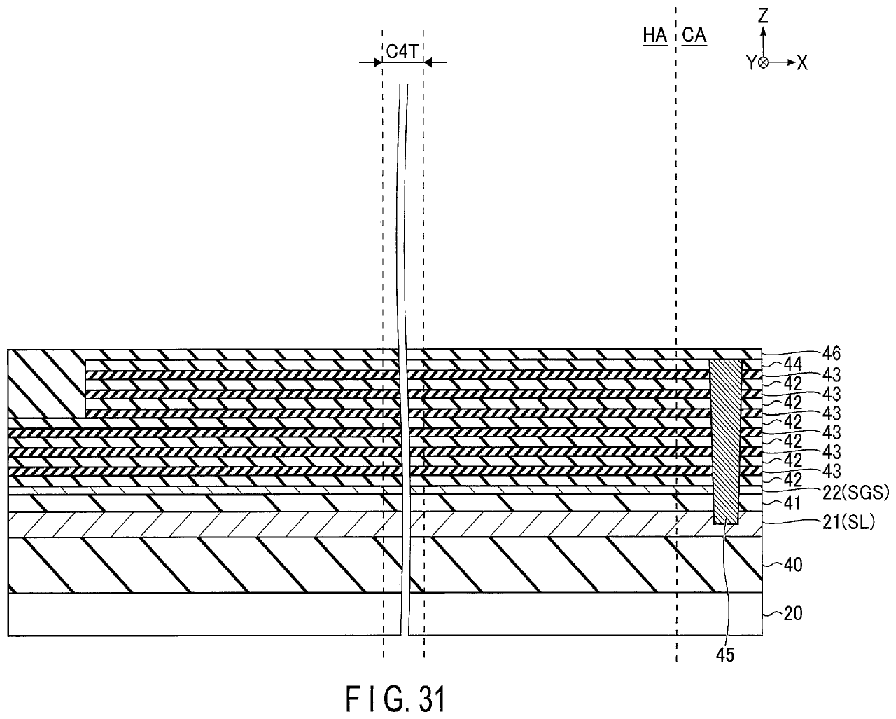

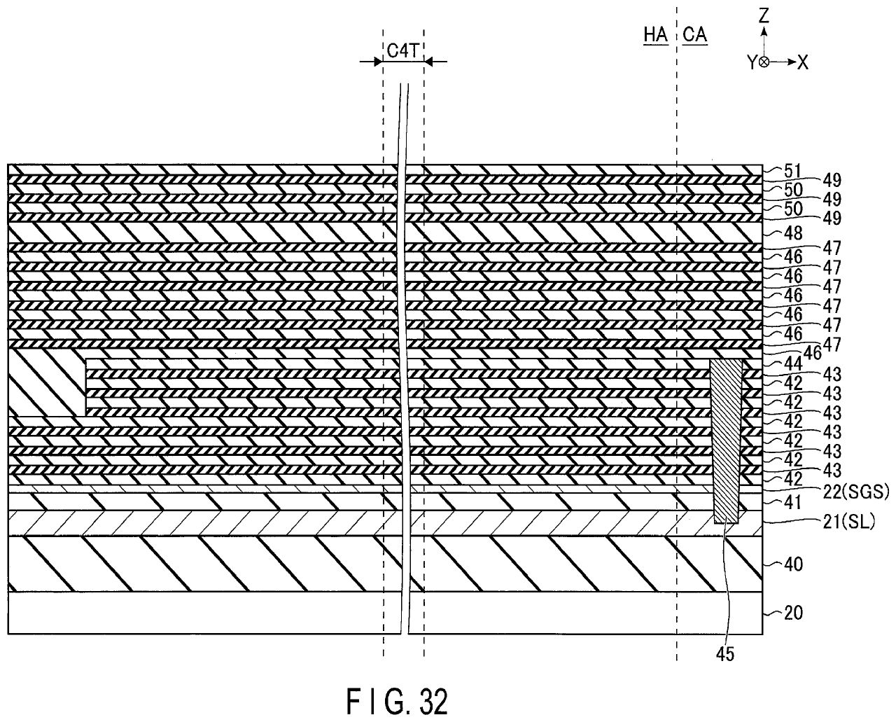

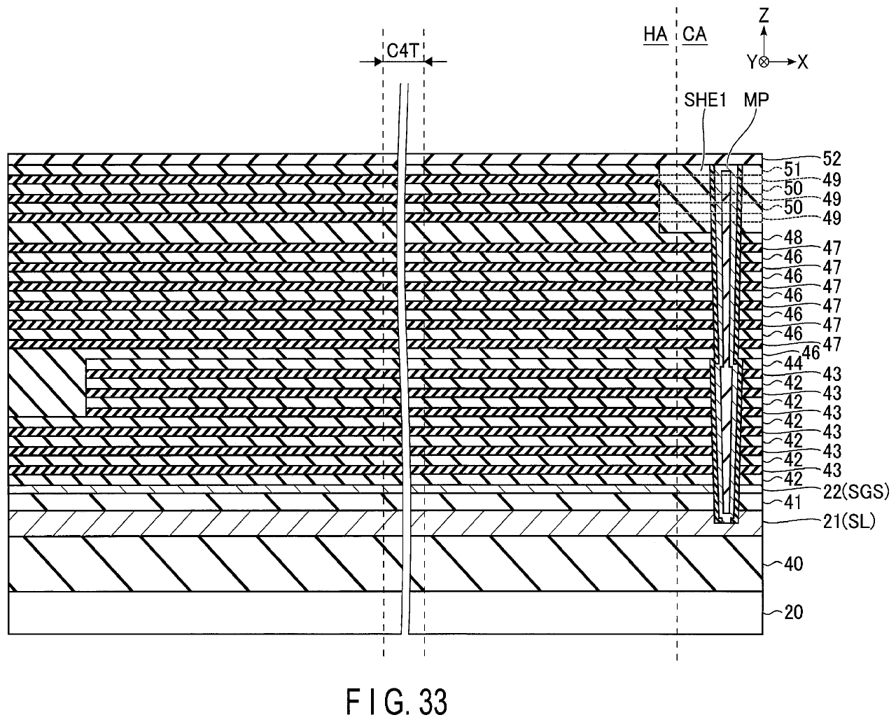

Hereinafter, referring to FIG. 30 as needed, a description will be given of an example of serial manufacturing steps relating to the formation of a stacked interconnect structure in the memory cell array 10 in the semiconductor memory device 1 according to the second embodiment. FIG. 30 is a flowchart illustrating an example of a manufacturing method of the semiconductor memory device 1 according to the second embodiment. Each of FIG. 31 to FIG. 34 illustrates an example of a cross-sectional structure during the manufacture of the semiconductor memory device 1 according to the second embodiment.

To begin with, the processes of steps S101 and S102 in the first embodiment are successively executed. Thereby, the same structure as the structure on the semiconductor substrate 20 in FIG. 14 and FIG. 15 described in the first embodiment is formed. In brief, the sacrificial members 43 are stacked, the memory holes LMH is formed, and the sacrificial member 45 is formed in the inside of the memory hole LMH.

Next, by a process of step S201, a stepped structure of the lower-layer interconnect portion is formed. Specifically, a mask covering, for example, a part of a stepped area in the hookup area HA is first formed by photolithography or the like. Then, Y-directional steps are formed in the sacrificial members 43 provided in the hookup area HA, by a combination of the anisotropic etching using the formed mask and a slimming process of the mask.

Subsequently, like the formation of the Y-directional steps, the formation of a mask covering a part of the stepped area in the hookup area HA, etching and slimming process are performed, and X-directional steps are formed in the sacrificial members 43 provided in the hookup area HA. Thereby, as illustrated in FIG. 31, a stepped structure corresponding to the lower-layer interconnect portion is formed in the stacked sacrificial members 43. Thereafter, an insulator layer 46 is formed in a manner to fill the part of the stepped structure in the hookup area HA, and a top surface of the insulator layer 46 is planarized by CMP or the like.

Next, the processes of steps S103 to S106 in the first embodiment are successively performed. Specifically, as illustrated in FIG. 32, sacrificial members 47 and 49 of the upper-layer interconnect portion are first stacked. At this time, the sacrificial members 47 and 49 are also stacked above the area where the stepped structure corresponding to the lower-layer interconnect portion is formed. Then, by the same method as in the first embodiment, a slit SHE1, a memory pillar MP and an insulator layer 52 are formed as illustrated in FIG. 33.

Next, by a process of step S202, a stepped structure of the upper-layer interconnect portion is formed. Specifically, a mask covering, for example, a part of a stepped area in the hookup area HA is first formed by photolithography or the like. Then, Y-directional steps are formed in the sacrificial members 47 provided in the hookup area HA, by a combination of the anisotropic etching using the formed mask and a slimming process of the mask.

Subsequently, like the formation of the Y-directional steps, the formation of a mask covering a part of the stepped area in the hookup area HA, etching and slimming process are performed, and X-directional steps are formed in the sacrificial members 47 and 49 provided in the hookup area HA. Thereby, as illustrated in FIG. 34, a stepped structure corresponding to the upper-layer interconnect portion is formed in the stacked sacrificial members 47 and 49. Thereafter, an insulator layer 53 is formed in a manner to fill the space formed on the stepped structure in the hookup area HA, and a top surface of the insulator layer 53 is planarized by CMP or the like.

Next, the processes of steps S108 to S111 in the first embodiment are successively executed. In brief, the formation of the slit SHE2, the formation of the support pillars HR and contracts C4, the formation of the slits SLT, and the replacement process of the stacked interconnect portions are carried out. Thereby, the memory pillars MP, and the source line SL, word lines WL and select gate lines SGDa, SGDb, SGDc and SGS, which are connected to the memory pillars MP, are formed.

The details of the other manufacturing steps in the semiconductor memory device 1 according to the second embodiment are the same as in the first embodiment, so a description of the details is omitted here. In the above description, the case in which the step of forming Y-directional steps is inserted in each of steps S201 and S202 was described by way of example. However, the embodiment is not limited this. For example, in the processing of the lower-layer interconnect portion in step S201, the step of forming Y-directional steps may be omitted. In this case, in step S202, the processing for forming the Y-directional steps in the lower-layer interconnect portion and the processing for forming the Y-directional steps in the upper-layer interconnect portion are executed batchwise.

[2-2] Advantageous Effects of the Second Embodiment

As described above, in the manufacturing method of the semiconductor memory device 1 according to the second embodiment, the stepped structure of the lower-layer interconnect portion is formed before the formation of the memory pillar MP. Specifically, in the manufacturing method of the semiconductor memory device 1 according to the second embodiment, at the time of forming the memory hole UMH, an influence of a distortion by the insulator layer 46 formed in the stepped part in the hookup area HA may occur in the stacked structure of the insulator layers and sacrificial layers in the cell area CA.

However, in the semiconductor memory device 1 according to the second embodiment, the total amount of the insulator layer 46 buried in the hookup area HA is much smaller than the total amount of the insulator layer which is buried in the case where the entire stepped structure in the hookup area HA is formed. Specifically, in the hookup area HA, the amount of distortion by the insulator layer 46 buried in association with the lower-layer interconnect portion is smaller than the amount of distortion by the insulator layer 53 which is buried when the stepped structure corresponding to the lower-layer interconnect portion and upper-layer interconnect portion is formed.

As a result, like the first embodiment, the semiconductor memory device 1 according to the second embodiment can suppress the occurrence of a defect due to the contacts CC of the select gate lines SGD, and the occurrence of a defect due to a misalignment between the memory holes LMH and UMH. In short, the semiconductor memory device 1 according to the second embodiment can improve the yield of semiconductor memory devices 1.

### [3] Third Embodiment

A semiconductor memory device 1 according to a third embodiment relates to a modification of the manufacturing method of the semiconductor memory device 1 described in the first embodiment, and the step of forming the slit SHE2 and the step of forming the slit SLT are integrated. Hereinafter, the semiconductor memory device 1 according to the third embodiment will be described with respect to different points from the first embodiment.

[3-1] Manufacturing Method of Semiconductor Memory Device 1

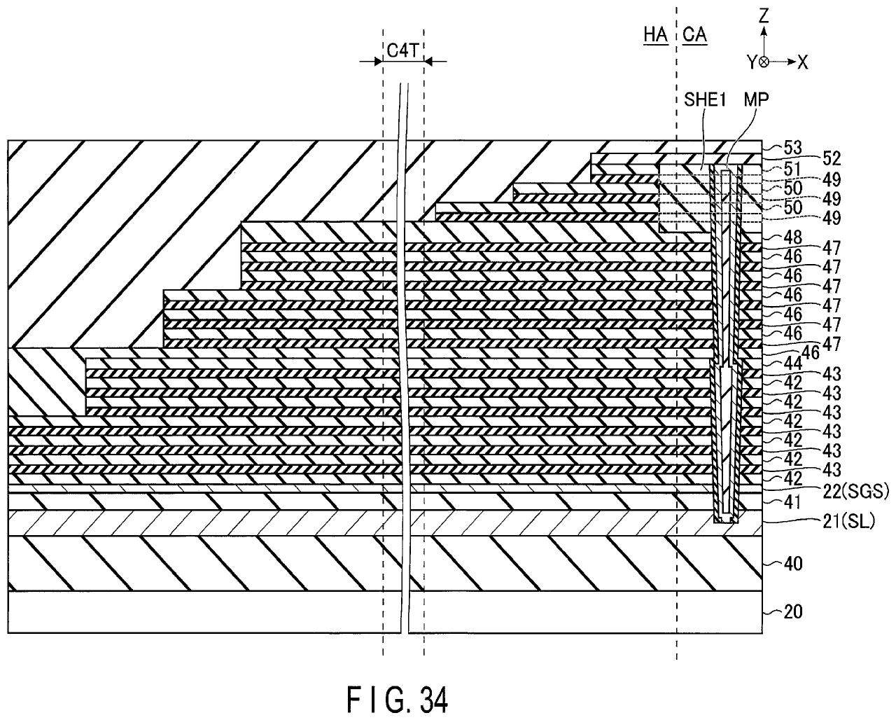

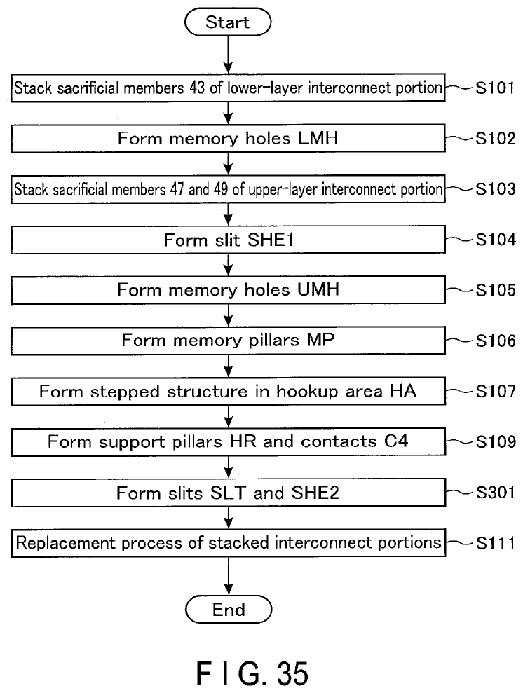

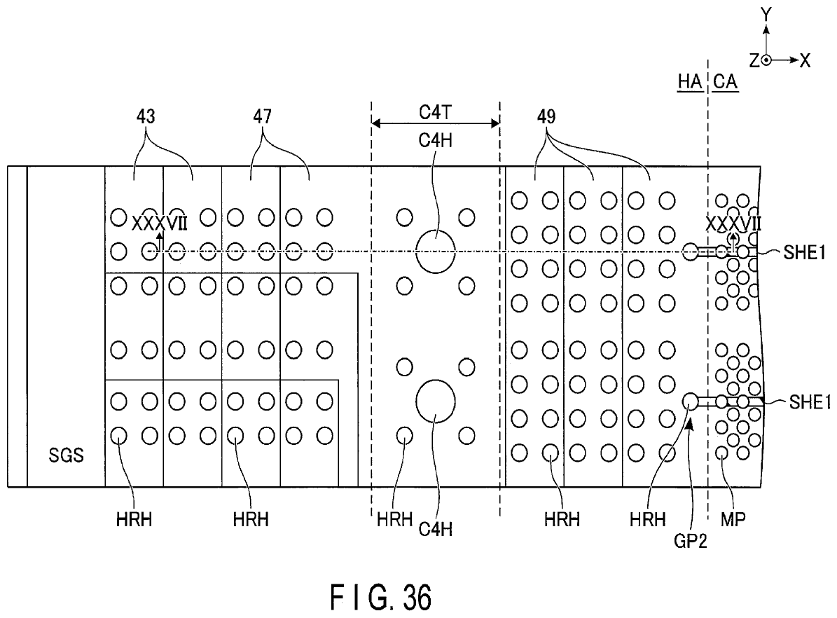

Hereinafter, referring to FIG. 35 as needed, a description will be given of an example of serial manufacturing steps relating to the formation of a stacked interconnect structure in the memory cell array 10 in the semiconductor memory device 1 according to the third embodiment. FIG. 35 is a flowchart illustrating an example of a manufacturing method of the semiconductor memory device 1 according to the third embodiment. Each of FIG. 36 to FIG. 39 illustrates an example of a planar layout or a cross-sectional structure during the manufacture of the semiconductor memory device 1 according to the third embodiment.

To begin with, the processes of steps S101 to S107 in the first embodiment are successively performed. Thereby, the same structure as the structure on the semiconductor substrate 20 in FIG. 21 described in the first embodiment is formed. In brief, the sacrificial members 43, 47 and 49 are stacked, the slit SHE1 is formed, the memory pillars MP is formed, and the stepped structure of the end portions of the sacrificial members 43, 47 and 49 is formed.

Next, by the process of step S109, support pillars HR and contacts C4 are formed. Specifically, a mask with openings in areas corresponding to the support pillars HR and contacts C4 is first formed by lithography or the like. Then, holes HRH and C4H are formed as illustrated in FIG. 36, by anisotropic etching using the formed mask.

Thereafter, an insulator layer 37 is formed on a side surface and bottom surface of the hole C4H and in the inside of the hole HRH, and the insulator layer 37 is buried in the inside of the hole HRH. In addition, a part of the insulator layer 37 formed in the bottom portion of the hole C4H is removed by etch-back, and subsequently a conductive layer 36 is buried in the inside of the hole C4H. The conductive layer 36 formed outside the hole C4H is removed by, for example, CMP.

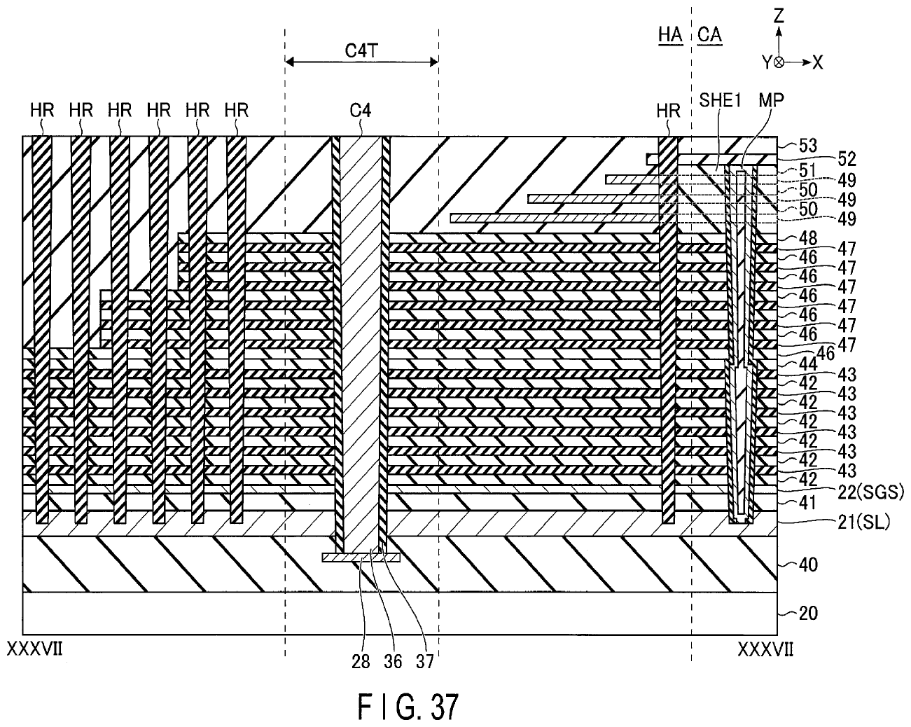

Thereby, as illustrated in FIG. 37, support pillars HR and contacts C4 are formed. Note that, as described in the first embodiment, the process of exposing the surface of the conductive layer 28 at the bottom portion of the hole C4H may be executed by etching which is different from the etching for simultaneously forming the holes HRH and C4H.

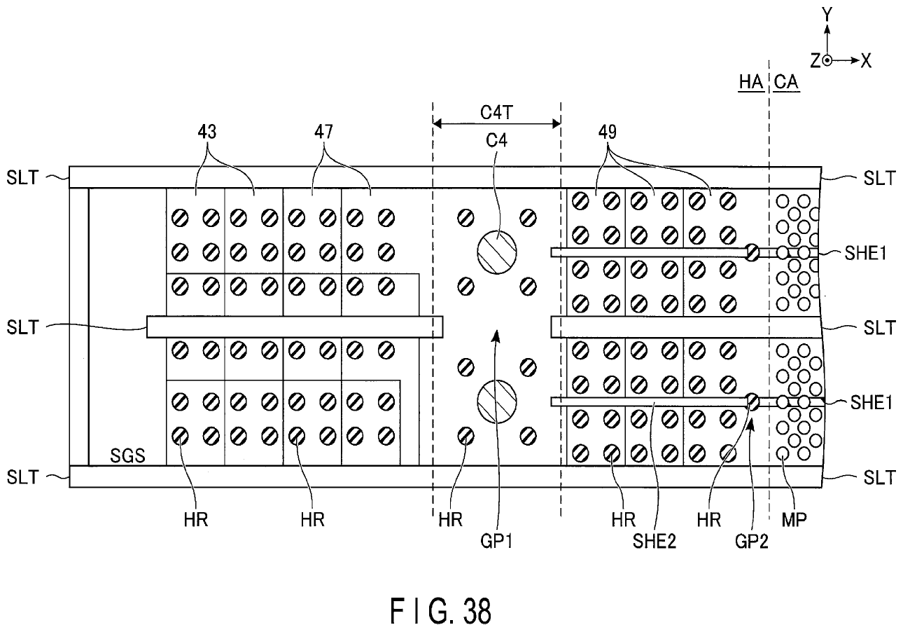

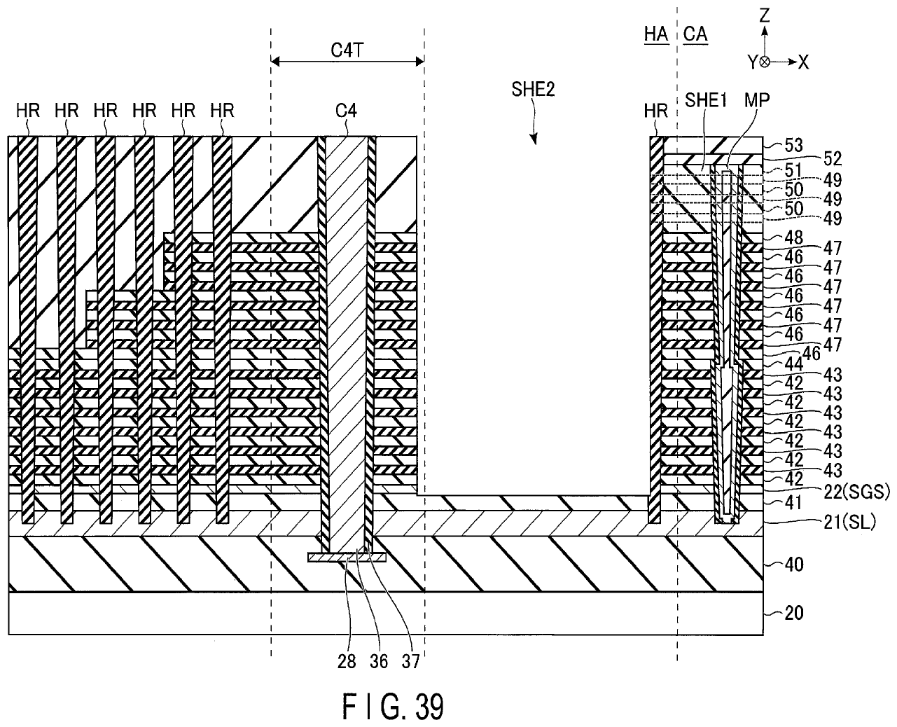

Next, by a process of step S301, slits SLT and SHE2 are formed as illustrated in FIG. 38. Specifically, a mask with openings in areas corresponding to slits SLT1, SLT2 and SLT3 and in areas corresponding to slits SHE2 is first formed by photolithography or the like. Then, the slits SLT and SHE2 are formed by anisotropic etching using the formed mask. Note that in the third embodiment, as illustrated in FIG. 39, the slit SHE2 may be formed such that the slit SHE2 not only divides the sacrificial members 49, but also penetrates, like the support pillar HR, the sacrificial members 43 and 47 and conductive layer 22 below the sacrificial members 49.

Next, by a process of step S111, a replacement process similar to the replacement process in the first embodiment is executed. Thereby, the memory pillars MP, and the source line SL, word lines WL and select gate lines SGDa, SGDb, SGDc and SGS, which are connected to the memory pillars MP, are formed. The details of the other manufacturing steps in the semiconductor memory device 1 according to the third embodiment are the same as in the first embodiment, so a description of the details is omitted here.

[3-2] Advantageous Effects of the Third Embodiment

As described above, in the manufacturing method of the semiconductor memory device 1 according to the third embodiment, the support pillar HR and contact C4 are formed before the formation of the slit SHE2. In addition, the processing of the slit SLT and the processing of the slit SHE2 are performed by the same manufacturing step.

As a result, the manufacturing method of the semiconductor memory device 1 according to the third embodiment can make smaller the number of manufacturing steps than in the first embodiment. Therefore, the semiconductor memory device 1 according to the third embodiment can reduce the manufacturing cost, in addition to the same advantageous effects as in the first embodiment.

### [4] Fourth Embodiment

In a semiconductor memory device 1 according to a fourth embodiment, as a dividing member which is disposed between the slits SHE1 and SHE2 and divides, together with the slits SHE1 and SHE2, the select gate lines SGD, use is made of a contact C4 in place of the support pillar HR in the first to third embodiments. Hereinafter, the semiconductor memory device 1 according to the fourth embodiment will be described with respect to different points from the first to third embodiments.

[4-1] Structure of Memory Cell Array 10

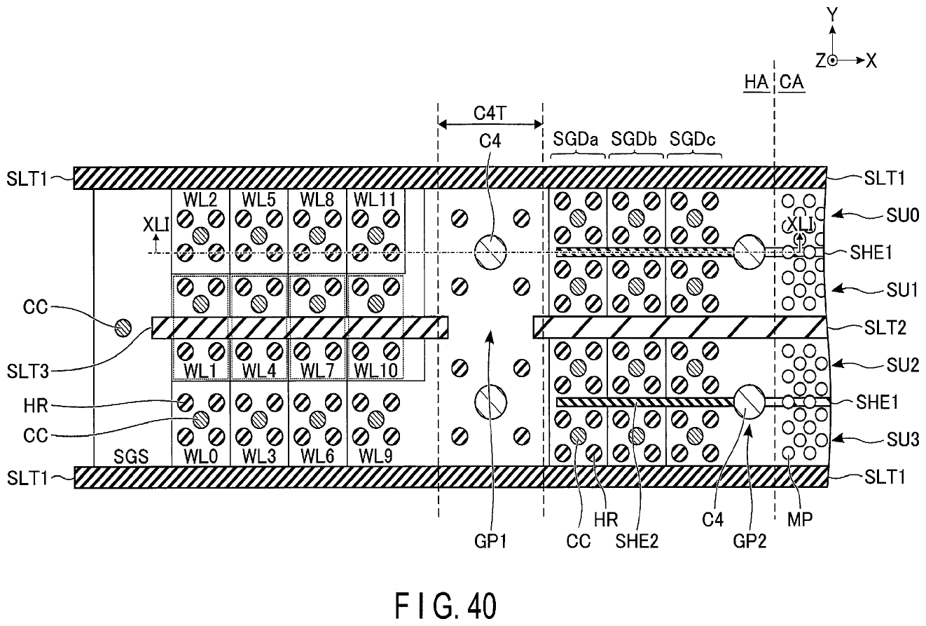

FIG. 40 illustrates an example of a detailed planar layout of the memory cell array 10 in the hookup area HA of the semiconductor memory device 1 according to the fourth embodiment, by extracting an area corresponding to one block BLK (i.e. string units SU0 to SU3). As illustrated in FIG. 40, the planar layout of the memory cell array 10 in the hookup area HA in the fourth embodiment differs from the planar layout of the memory cell array 10 described with reference to FIG. 7 in the first embodiment, with respect to constituent elements disposed in the gap portion GP2.

Specifically, in the semiconductor memory device 1 according to the fourth embodiment, the contact C4 in place of the support pillar HR is disposed in the gap portion GP2. In other words, in the semiconductor memory device 1 according to the fourth embodiment, the contact C4 is disposed between the paired slits SHE1 and SHE2 which is adjacent in the X direction.

Thereby, in the semiconductor memory device 1 according to the fourth embodiment, the select gate lines SGDa, SGDb and SGDc between the two adjacent slits SLT1 are separated by the paired slits SHE1 and SHE2 adjacent in the X direction, the contact C4 between the slits SHE1 and SHE2, and the memory pillars MP overlapping the slit SHE1.

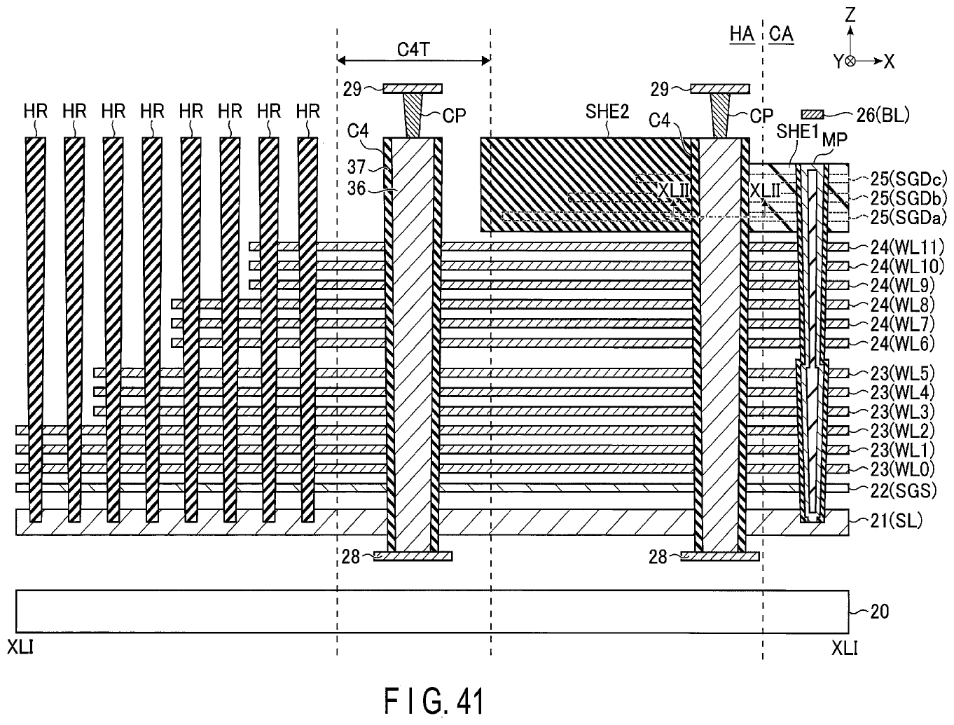

FIG. 41 is a cross-sectional view, taken along line XLI-XLI in FIG. 40, illustrating an example of a cross-sectional structure in the hookup area HA of the memory cell array 10 included in the semiconductor memory device 1 according to the fourth embodiment. As illustrated in FIG. 41, in the fourth embodiment, the contact C4 is disposed between the slits SHE1 and SHE2, and the contact C4 penetrates the stacked conductive layers 25, too. The conductive layer 36 in the contact C4 is insulated by the insulator layer 37 from the conductive layers 25 which the contact C4 penetrates.

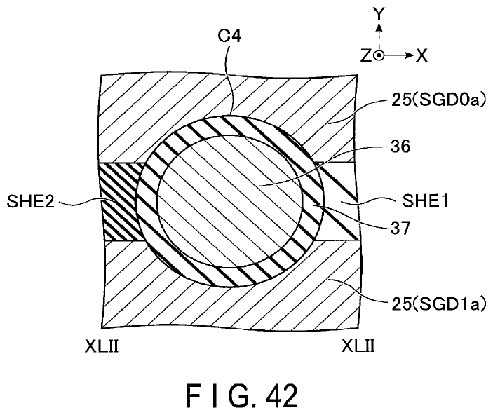

FIG. 42 is a cross-sectional view, taken along line XLII-XLII in FIG. 41, illustrating an example of a cross-sectional structure of the contact C4 in the semiconductor memory device 1 according to the fourth embodiment. More specifically, FIG. 42 illustrates a cross-sectional structure of the contact C4 provided between the adjacent slits SHE1 and SHE2, in a layer which is parallel to the surface of the semiconductor substrate 20 and includes the conductive layer 25.

As illustrated in FIG. 42, in the layer including the conductive layer 25, the contact C4 between the slits SHE1 and SHE2 is in contact with, for example, an end portion of the slit SHE1, an end portion of the slit SHE2, a conductive layer 25 corresponding to a select gate line SGD0a, and a conductive layer 25 corresponding to a select gate line SGD1a. Specifically, the contact C4 between the slits SHE1 and SHE2 is in contact with each of the two select gate lines SGD (conductive layers 25) which are provided in the same interconnect layer and are adjacent each other. The other configuration of the semiconductor memory device 1 according to the fourth embodiment is the same as in the semiconductor memory device 1 according to the first embodiment, so a description thereof is omitted here.

[4-2] Manufacturing Method of Semiconductor Memory Device 1

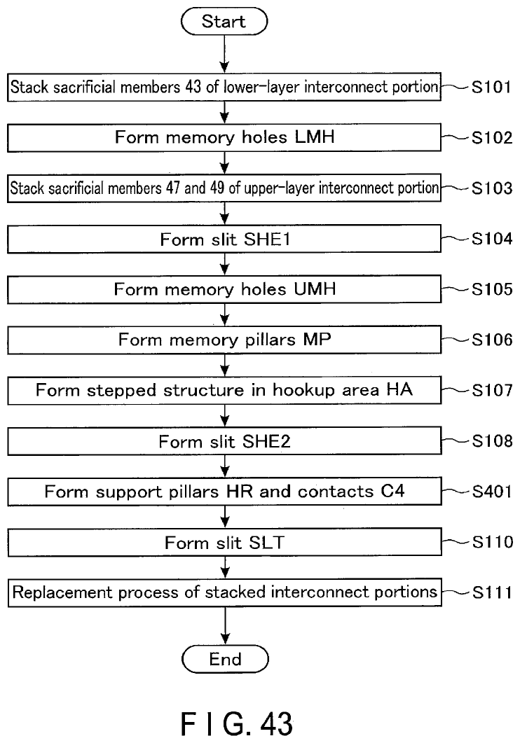

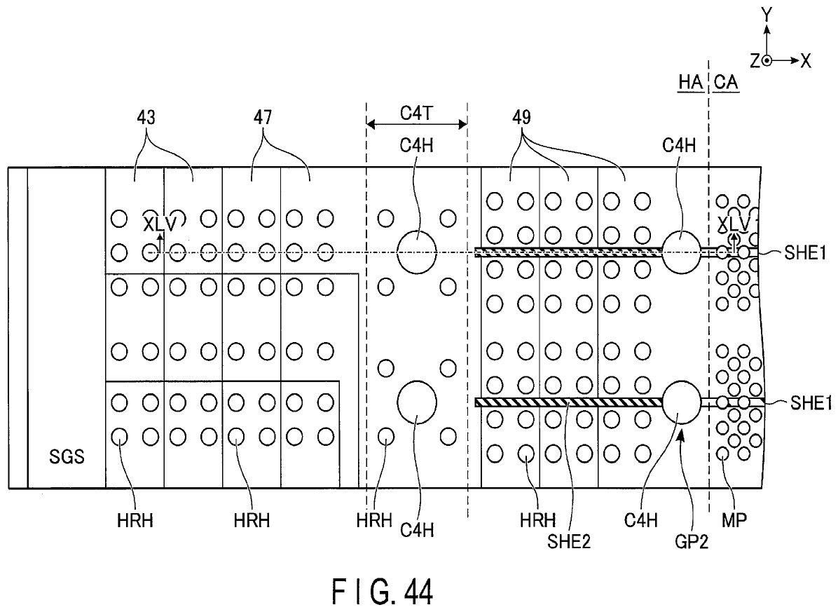

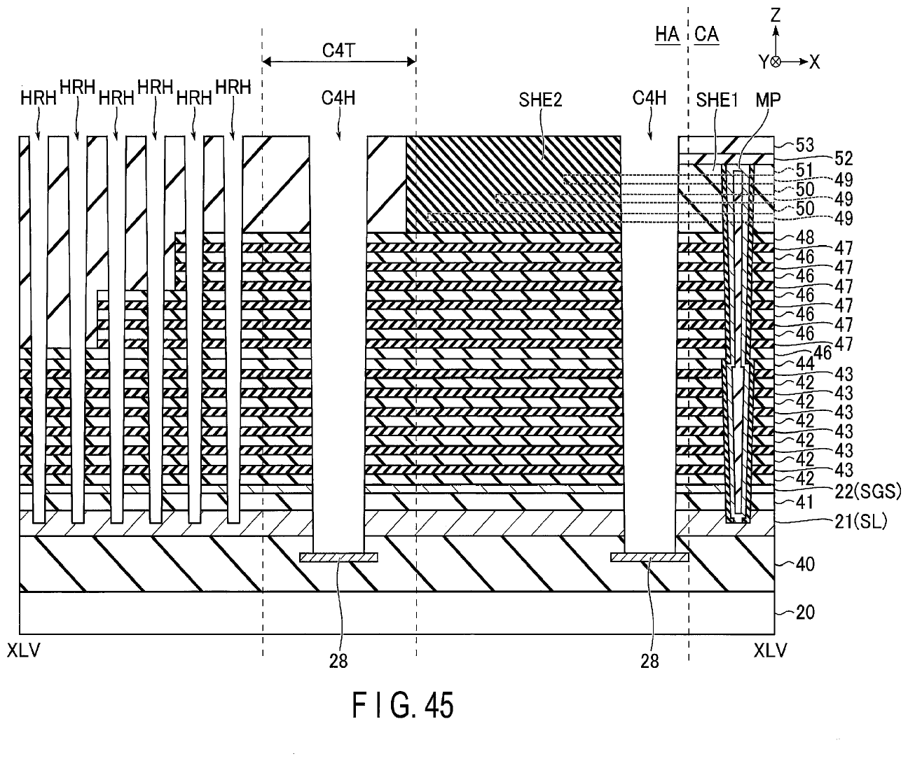

Hereinafter, referring to FIG. 43 as needed, a description will be given of an example of serial manufacturing steps relating to the formation of a stacked interconnect structure in the memory cell array 10 in the semiconductor memory device 1 according to the fourth embodiment. FIG. 43 is a flowchart illustrating an example of a manufacturing method of the semiconductor memory device 1 according to the fourth embodiment. FIG. 44 to FIG. 45 illustrate examples of a planar layout and a cross-sectional structure during the manufacture of the semiconductor memory device 1 according to the fourth embodiment.

To begin with, the processes of steps S101 to S108 in the first embodiment are successively executed. Thereby, the same structure as the structure on the semiconductor substrate 20 in FIG. 22 and FIG. 23 described in the first embodiment is formed. In brief, the sacrificial members 43, 47 and 49 are stacked, the slits SHE1 and SHE2 are formed, the memory pillars MP are formed, and the stepped structure of the end portions of the sacrificial members 43, 47 and 49 is formed.

Next, by a process of step S401, support pillars HR and contacts C4 are formed. Specifically, a mask with openings in areas corresponding to the support pillars HR and contacts C4 is first formed by photolithography or the like. Then, as illustrated in FIG. 44 and FIG. 45, holes HRH and C4H are formed by anisotropic etching using the formed mask. The holes C4H formed in the fourth embodiment include a hole C4H which is provided in a manner to overlap the end portions of the slits SHE1 and SHE2 which are adjacent in the X direction.

Thereafter, an insulator layer 37 is formed on a side surface and bottom surface of the hole C4H and in the inside of the hole HRH, and the insulator layer 37 is buried in the inside of the hole HRH. In addition, a part of the insulator layer 37 formed in the bottom portion of the hole C4H is removed by etch-back, and subsequently a conductive layer 36 is buried in the inside of the hole C4H. The conductive layer 36 formed outside the hole C4H is removed by, for example, CMP. Thereby, the support pillars HR and contacts C4 are formed.

Next, by the processes of steps S110 and S111 in the first embodiment, the formation of the slits SLT and the replacement process of the stacked interconnect portions are carried out. Thereby, the memory pillars MP, and the source line SL, word lines WL and select gate lines SGDa, SGDb, SGDc and SGS, which are connected to the memory pillars MP, are formed. The details of the other manufacturing steps in the semiconductor memory device 1 according to the fourth embodiment are the same as in the first embodiment, so a description of the details is omitted here.

[4-3] Advantageous Effects of the Fourth Embodiment

As described above, the semiconductor memory device 1 according to the fourth embodiment has such a structure that the support pillar HR disposed in the gap portion GP2 is replaced with the contact C4. Like the support pillar HR in the first embodiment, the contact C4 disposed in the gap portion GP2 is used as a structure which couples the adjacent slits SHE1 and SHE2.

Thereby, like the first embodiment, the semiconductor memory device 1 according to the fourth embodiment can suppress the occurrence of a defect due to the contacts CC of the select gate lines SGD, and the occurrence of a defect due to a misalignment between the memory holes LMH and UMH. In short, the semiconductor memory device 1 according to the fourth embodiment can improve the yield of semiconductor memory devices 1.

### [5] Other Modifications, Etc.

A semiconductor memory device according to an embodiment includes a substrate, a plurality of first conductive layers, a second conductive layer, a third conductive layer, a first pillar, a second pillar, a first contact, a second contact, a first member, a second member, and a third member. The substrate includes a first area and a second area adjacent to the first area. The plurality of first conductive layers are provided above the substrate of the first area and the second area. The first conductive layers are stacked at intervals in a first direction. The second conductive layer is provided above an uppermost first conductive layer of the first conductive layers. The third conductive layer is provided above the uppermost first conductive layer and is provided in the same layer as the second conductive layer. The third conductive layer and the second conductive layer are separated from each other. The first pillar is provided to penetrate the first conductive layers and the second conductive layer in the first area. An intersection portion between the first pillar and each of the first conductive layers functions as a memory cell transistor. An intersection portion between the first pillar and the second conductive layer functions as a select transistor. A second pillar is provided to penetrate the first conductive layers and the third conductive layer in the first area. An intersection portion between the second pillar and each of the first conductive layers functions as a memory cell transistor. An intersection portion between the second pillar and the third conductive layer is functions as a select transistor. The first contact is provided on the second conductive layer in the second area. The second contact is provided on the third conductive layer in the second area. The first member is provided between the second conductive layer and the third conductive layer in the first area. The second member is provided between the second conductive layer and the third conductive layer in the second area. The third member is extending in the first direction and is provided to penetrate the first conductive layers. The third member is in contact with each of the second conductive layer, the third conductive layer, the first member and the second member. Thereby, the yield of semiconductor memory devices can be improved.

The method in which the stepped structure of the lower-layer interconnect portion and the stepped structure of the upper-layer interconnect portion are formed in different manufacturing steps, as in the second embodiment, is also applicable to the other embodiments. The method in which the slit SHE2 and slit SLT are processed in the same step, as in the third embodiment, is applicable to the first embodiment.

In the above-described embodiments, the configuration of the memory cell array 10 may be some other configuration. For example, the memory pillars MP may be configured such that three or more pillars are coupled in the Z direction. In addition, the memory pillars MP may be configured such that a pillar corresponding to the select gate lines SGD and a pillar corresponding to the word lines WL are coupled. An inside of the slit SLT may be composed of a plurality of kinds of insulators. The number of bit lines BL overlapping each memory pillar MP may be freely selected.

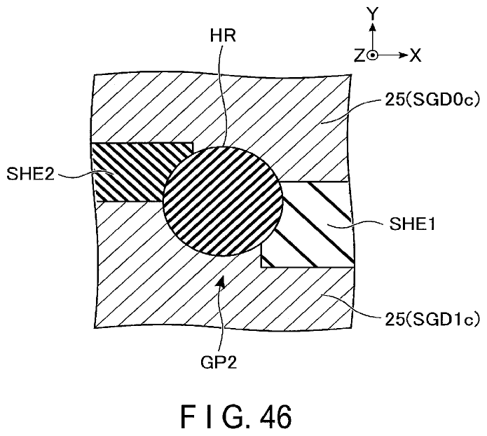

The drawings used in the descriptions of the above embodiments illustrate the case in which the thickness (e.g. the width in the Y direction) of the slit SHE1 and the thickness of the slit SHE2 are substantially equal, but the embodiments are not limited to this. FIG. 46 illustrates an example of a cross-sectional structure of a support pillar HR in a modification of the first embodiment, and this cross-sectional structure corresponds to an area similar to the area illustrated in FIG. 11. As illustrated in FIG. 46, the thickness of the slit SHE1 and the thickness of the slit SHE2 in the above-described embodiments may be different.

In addition, the positions of the slits SHE1 and SHE2 in the Y direction may be mutually displaced. The slits SHE1 and SHE2 may have any shapes or dispositions, if the adjacent slits SHE1 and SHE2 are, at least, coupled by the support pillar HR disposed in the gap portion GP2. Similarly, the slits SHE1 and SHE2 in the fourth embodiment may have any shapes or dispositions, if the adjacent slits SHE1 and SHE2 are, at least, coupled by the contact C4 disposed in the gap portion GP2. Further, in the above-described embodiments, insofar as each of the slits SHE1 and SHE2 divides at least all of the stacked conductive layers 25, each of the slits SHE1 and SHE2 may also divide some of the conductive layers corresponding to the word lines WL.

In the present specification, the slit SHE1 is defined as the “slit SHE1 provided to extend in the X direction”. However, the slit SHE1 may be divided by the memory pillar MP, and may have a discontinuous structure. For example, when the memory pillar MP and slit SHE1 overlap, the slits SHE1 (insulator members) divided by the memory pillar MP may be disposed to extend across the memory pillar MP in the X direction.

In the above-described embodiments, the case was exemplarily described in which, in the hookup area HA, the end portions of the word lines WL0 to WL11 are provided in a stepped shape of three rows, the stepped shape including two steps in the Y direction and a plurality of steps in the X direction. However, the embodiments are not limited to this. The number of steps formed in the Y direction in the end portions of the stacked word lines WL may be freely selected. Specifically, in the semiconductor memory device 1, the end portions of the word lines WL in the hookup area HA may be designed in a stepped shape of a freely selected number of rows.

In the above-described embodiments, the case was exemplarily described in which the semiconductor memory device 1 is configured such that circuitry such as the sense amplifier module 16 is provided below the memory cell array 10. However, the embodiments are not limited to this. For example, the semiconductor memory device 1 may be configured such that the memory cell array 10 and sense amplifier module 16 are formed above the semiconductor substrate 20. Further, the semiconductor memory device 1 may be configured such that a chip provided with the sense amplifier module 16 or the like and a chip provided with the memory cell array 10 are bonded together.

In the above-described embodiments, the configuration was described in which the word lines WL and select gate line SGS are adjacent and the word lines WL and select gate lines SGD are adjacent. However, the embodiments are not limited to this. For example, a dummy word line corresponding to a dummy transistor may be provided between the uppermost word line WL and the select gate lines SGD. Similarly, a dummy word line may be provided between the lowermost word line WL and the select gate line SGS. Further, a conductive layer near a joint portion of pillars coupled in the Z direction may be used as a dummy word line.

The drawings used in the descriptions of the above embodiments illustrate the case in which the support pillar HR and contact C4 have taper shapes. However, the embodiments are not limited to this. For example, the support pillar HR and contact C4 may have inverse taper shapes, or may shapes with bulging intermediate portions. Similarly, the slit SLT and slit SHE may have inverse taper shapes, or may have shapes with bulging intermediate portions. Besides, in the above-described embodiments, the case was exemplarily described in which the cross-sectional shape of each of the support pillar HR, contact C4 and memory pillar MP is circular. However, this cross-sectional shape may be elliptic, or may be a freely designed shape.

In the above-described embodiments, the case was exemplarily described in which the semiconductor layer 31 and conductive layer 21 are electrically connected via the bottom portion of the memory pillar MP. However, the embodiments are not limited to this. The semiconductor layer 31 and conductive layer 21 may be electrically connected via a side surface of the memory pillar MP. In this case, a part of the stacked film 32 formed in a side surface portion of the memory pillar MP is removed, and a structure is formed in which the semiconductor layer 31 and conductive layer 21 are in contact with each other via the removed part. In addition, the stacked film 32 in each memory pillar MP may be configured such that the insulator film 34 and tunnel insulator film 33 are successively formed in the memory hole. The block insulator film 35 may be formed on peripheries of the conductive layers 23 to 25 including the side-surface side of the insulator film 34, when the replacement process of the stacked interconnects is executed.

In the present specification, the term “connection” means an electrical connection, and does not exclude, for example, a connection with another element being interposed. In addition, the expression “electrically connected” may also mean “electrically connected via an insulator” if the same operation as “electrically connected” is enabled. The expression “successively provided” means the formation by the same manufacturing step. No boundary is formed in a successively provided part in a certain constituent element. The expression “successively provided” has the same meaning as a continuous film from a first portion to a second portion in a certain film or layer.

In the present specification, the term “columnar shape” means a structure provided in a hole formed in a manufacturing step of the semiconductor memory device 1. A structure formed in each of the memory hole LMH and UMH may be referred to as “pillar”. Specifically, in the first embodiment, the memory pillar MP has such a structure that a pillar corresponding to the memory hole UMH is formed on a pillar corresponding to the memory hole LMH.

In the present specification, the term “outside diameter” means a diameter of a constituent element in a cross section parallel to the surface of the semiconductor substrate 20. In addition, the term “outside diameter” is measured by using, for example, an outermost peripheral member among members in a hole, which are used to form a constituent element that is a target of measurement. For example, when an outside diameter of the contact C4 and an outside diameter of the support pillar HR are compared, the outside diameters of constituent elements included in the same cross section are compared.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a substrate including a first area and a second area adjacent to the first area;
a plurality of first conductive layers provided above the substrate of the first area and the second area, the first conductive layers being stacked at intervals in a first direction;
a second conductive layer provided above an uppermost first conductive layer of the first conductive layers;
a third conductive layer provided above the uppermost first conductive layer and provided in the same layer as the second conductive layer, the third conductive layer and the second conductive layer being separated from each other;
a first pillar provided to penetrate the first conductive layers and the second conductive layer in the first area, an intersection portion between the first pillar and each of the first conductive layers functioning as a memory cell transistor, and an intersection portion between the first pillar and the second conductive layer functioning as a select transistor;
a second pillar provided to penetrate the first conductive layers and the third conductive layer in the first area, an intersection portion between the second pillar and each of the first conductive layers functioning as a memory cell transistor, and an intersection portion between the second pillar and the third conductive layer functioning as a select transistor;
a first contact provided on the second conductive layer in the second area;
a second contact provided on the third conductive layer in the second area;
a first member provided between the second conductive layer and the third conductive layer in the first area;
a second member provided between the second conductive layer and the third conductive layer in the second area; and
a third member extending in the first direction and provided to penetrate the first conductive layers, the third member being in contact with each of the second conductive layer, the third conductive layer, the first member and the second member.

2. The device of claim 1, wherein
the third member includes an insulator, and no contact is provided on the third member.

3. The device of claim 1, further comprising:
a fourth conductive layer provided between the substrate and the third member; and
a fifth conductive layer provided above the third member, wherein
the third member includes a sixth conductive layer and a first insulator film, the sixth conductive layer being provided to extend in the first direction and connecting the fourth conductive layer and the fifth conductive layer, and the first insulator film covering a side surface of the sixth conductive layer.

4. The device of claim 1, wherein
the first conductive layers are classified into a first stacked structure including the uppermost first conductive layer, and a second stacked structure including a lowermost first conductive layer of the first conductive layers,
the first pillar includes a first portion penetrating the first conductive layers of the first stacked structure, and a second portion penetrating the first conductive layers of the second stacked structure, and
an outside diameter at a lower end of the first portion is less than an outside diameter at an upper end of the second portion.

5. The device of claim 1, wherein
a distance in the first direction between a surface of the substrate and an upper end of the first member is less than a distance in the first direction between the surface of the substrate and an upper end of the second member.

6. The device of claim 1, wherein
a dimension in a second direction, which crosses the first direction and a direction of extension of the second conductive layer, is different between the first member and the second member.

7. The device of claim 1, wherein
a position of the first member and a position of the second member are displaced from each other in a second direction which crosses the first direction and a direction of extension of the second conductive layer.

8. The device of claim 1, further comprising:
a third pillar penetrating the first conductive layers and the first member.

9. The device of claim 8, wherein
no contact is provided on the third pillar.

10. The device of claim 8, wherein
the third pillar is in contact with each of the second conductive layer and the third conductive layer.

11. The device of claim 8, wherein
each of the first pillar, the second pillar and the third pillar includes a first semiconductor layer which is provided to extend in the first direction, and a second insulator film which covers a side surface of the first semiconductor layer.

12. The device of claim 1, further comprising:
a seventh conductive layer provided between the second conductive layer and the uppermost first conductive layer, the first pillar penetrating the seventh conductive layer in the first area;
an eighth conductive layer provided between the third conductive layer and the uppermost first conductive layer, the second pillar penetrating the eighth conductive layer in the first area;
a third contact provided on the seventh conductive layer in the second area; and
a fourth contact provided on the eighth conductive layer in the second area, wherein
each of the first member, the second member and the third member is further provided between the seventh conductive layer and the eighth conductive layer, and
the third member is further in contact with the seventh conductive layer and the eighth conductive layer.

13. The device of claim 1, wherein
the second member divides the first conductive layers.

14. The device of claim 1, wherein
each of the first member and the second member includes an insulator, and
the second conductive layer and the third conductive layer are separated by the first member, the second member and the third member.

15. The device of claim 1, wherein
the first conductive layers function as word lines, and
the second conductive layer and the third conductive layer function as mutually different select gate lines.

16. The device of claim 1, wherein
The first area is an area in which a memory cell transistor is formed, and
the second area is an area in which a contact that is connected to a word line or a select gate line is formed.

17. A method of manufacturing a semiconductor memory device, comprising:
forming, in a first area and a second area adjacent to the first area, a first stacked portion in which a plurality of first sacrificial members are stacked at intervals in a first direction, and forming a second sacrificial member above the first stacked portion, the second sacrificial member being separated from the first stacked portion;
forming a first slit penetrating the second sacrificial member in the first area in the first direction and extending in a direction in which the first area and the second area are adjacent each other;
forming a first hole penetrating the first stacked portion and the second sacrificial member in the first area;
successively forming at least a charge storage layer, a tunnel insulator film and a semiconductor layer in the first hole;
processing end portions of the first sacrificial members in a stepped shape in the second area;
forming, after the processing, a second slit penetrating the second sacrificial member in the second area in the first direction and extending in the direction in which the first area and the second area are adjacent each other;
forming, after the forming of the second slit, a second hole which overlaps an end portion of the first slit and an end portion of the second slit and penetrates the first stacked portion and the second sacrificial member in the first direction;
forming, after forming a dividing member of the second sacrificial member in the first slit, the second slit and the second hole, a third slit extending, in a position different from the first slit and the second slit, in the direction in which the first area and the second area are adjacent each other, the third slit dividing the first stacked portion and the second sacrificial member; and
removing, after the forming of the third slit, the first sacrificial members and the second sacrificial member, and forming conductors in spaces from which the first sacrificial members and the second sacrificial member are removed.

18. The method of claim 17, further comprising:
prior to the forming of the first stacked portion,
forming a second stacked portion in which a plurality of third sacrificial members are stacked at intervals in the first direction in the first area and the second area,
forming, after the forming of the second stacked portion, a third hole which penetrates the second stacked portion in the first area, and
forming a fourth sacrificial member in the third hole; and
exposing, at a time of forming the first hole, the fourth sacrificial member in a bottom portion of the first hole, and removing, prior to the successively forming, the fourth sacrificial member.

19. The method of claim 18, further comprising:
processing, after the forming of the fourth sacrificial member and before the forming of the first stacked portion, end portions of the third sacrificial members in a stepped shape in the second area.

20. A method of manufacturing a semiconductor memory device, comprising:
forming, in a first area and a second area adjacent to the first area, a first stacked portion in which a plurality of first sacrificial members are stacked at intervals in a first direction, and forming a second sacrificial member above the first stacked portion, the second sacrificial member being separated from the first stacked portion;
forming a first slit penetrating the second sacrificial member in the first area in the first direction and extending in a direction in which the first area and the second area are adjacent each other;
forming a first hole penetrating the first stacked portion and the second sacrificial member in the first area;
successively forming at least a charge storage layer, a tunnel insulator film and a semiconductor layer in the first hole;
processing end portions of the first sacrificial members in a stepped shape in the second area;
forming, after the processing, a second hole which overlaps an end portion of the first slit and penetrates the first stacked portion and the second sacrificial member in the first direction;
forming, after forming a dividing member of the second sacrificial member in the first slit and the second hole, a second slit including a portion overlapping the second hole, penetrating at least the second sacrificial member in the second area in the first direction and extending in the direction in which the first area and the second area are adjacent each other, and a third slit extending, in a position different from the first slit and the second slit, in the direction in which the first area and the second area are adjacent each other, the third slit dividing the first stacked portion and the second sacrificial member; and
removing, after the forming of the second slit and the third slit, the first sacrificial members and the second sacrificial member, and forming conductors in spaces from which the first sacrificial members and the second sacrificial member are removed.
